(19) United States
(12) Patent Application Publication
(10) Pub. No.: US 2008/0010845 A1
(43) Pub. Date: Jan. 17, 2008

(54) Apparatus for cleaning a wafer substrate

(75) Inventors: Joel Brad Bailey, Austin, TX (US); Jean-Michel Claude Huret, Cedar Park, TX (US); Paul F. Forderhase, Austin, TX (US); Satish Sadam, Round Rock, TX (US); Scott Allen Stratton, Pflugerville, TX (US); Michael D. Robbins, Round Rock, TX (US)

Correspondence Address: HARNESS, DICKEY & PIERCE, P.L.C., P.O. BOX 828, BLOOMFIELD HILLS, MI, 48303, US

(73) Assignee: Accretech USA, Inc., Bloomfield Hills, MI (US)

(21) Appl. No.: 11/825,670

(22) Filed: Jul. 6, 2007

Related U.S. Application Data
(63) Continuation-in-part of application No. 11/131,611, filed on May 18, 2005.
Application No. 11/131,611 is a division of application No. 10/401,074, filed on Mar. 27, 2003, now Pat. No. 6,936,546.
(63) Continuation-in-part of application No. 11/230,261, filed on Sep. 19, 2005.
(63) Continuation-in-part of application No. 11/230,263, filed on Sep. 19, 2005.
(63) Continuation-in-part of application No. 11/417,297, filed on May 2, 2006.
(60) Provisional application No. 60/819,521, filed on Jul. 7, 2006.
(60) Provisional application No. 60/376,154, filed on Apr. 26, 2002.

(51) Int. Cl. G01C 25/00; G01D 21/00; G06F 17/17; H01L 21/68

(52) U.S. Cl. 33/520; 414/757; 702/150

(57) ABSTRACT

A method and apparatus for dry chemical processing a wafer at atmospheric pressure is disclosed. The edge area of a substrate is placed in isolation from the remainder of the substrate. According to the present teachings, a method for centering a wafer on a rotatable chuck is provided. The method includes the steps of positioning a wafer adjacent to a micrometer. The wafer is then rotated and a plurality of wafer edge locations and rotational increments are measured. A center offset value for the value of the wafer center with respect to a chuck is calculated. The wafer is then moved with respect to a center position of the chuck.

### CROSS-REFERENCE TO RELATED APPLICATIONS

This application claims the benefit of U.S. Provisional Application No. 60/819,521, filed on Jul. 7, 2006. This application is a continuation-in-part of U.S. patent application Ser. No. 11/131,611, filed on May 18, 2005, which is a divisional application of Ser. No. 10/401,074, filed on May 27, 2003, now U.S. Pat. No. 6,936,546, issued Aug. 30, 2005, which claims priority U.S. Provisional Application 60/376,154, filed Apr. 26, 2002. This application is also a continuation-in-part of U.S. patent application Ser. No. 11/230,261, filed Sep. 19, 2005. This application is also a continuation-in-part of U.S. patent application Ser. No. 11/230,263, filed Sep. 19, 2005. This application is also a continuation-in-part of U.S. patent application Ser. No. 11/417,297, filed May 2, 2006. The disclosure of the above applications are incorporated herein by reference.

### FIELD

The present disclosure relates to a method and apparatus for processing of a substrate. More particularly, a method and apparatus for concentrically positioning a substrate relative to an apparatus for processing the edge of the substrate is disclosed. Furthermore, a seal arrangement for the alignment apparatus is also provided. In addition, processes for dry etching of a substrate with a combustion flame are disclosed.

### BACKGROUND

The statements in this section merely provide background information related to the present disclosure and may not constitute prior art.

During the manufacture of integrated circuits, silicon substrate wafers receive extensive processing including deposition and etching of dielectrics, metals, and other materials. At varying stages in the manufacturing process it is beneficial to “clean” the edge area of the wafer to remove unwanted films and contaminants including particles that develop as a result of the wafer processing.

This includes films and contaminants that develop on a near edge top surface (primary processed side), near edge back surface, and edge (including, top bevel, crown and bottom bevel) of the wafer (hereinafter “edge area” refers generally to the near edge top surface, near edge bottom surface, and edge in combination or individually). Removal of films and contaminants is desirable to prevent the potential of particulate migration into the device portion of the wafer. Potential contaminant particles are generated during wafer handling, processing, and as a result of “pop-off” effect due to film stress.

It is a challenge to process and thus remove edge area thin films and contaminants in an efficient and cost effective manner without affecting the remainder of the wafer that contains in-process devices. This challenge is exacerbated by use of chemistries and processes that may adversely impact the in-process device portion of the wafer.

Many of the existing film removal techniques fail to properly remove polymers, edge beads, dielectric or tantalum, particularly from the edge area, as may be desired by the wafer manufacturer. Specifically, it is desirable to maximize the usable surface area of a wafer thus minimizing any unusable edge area with the objective of maximizing die yield. Reduction in functional die produced from the usable surface area is termed yield loss and is generally undesirable and has a negative cost impact. Accordingly, a need in the art exists for improved processing methods and apparatus to remove various front side, back side and edge area films and contaminants in a cost effective and efficient manner.

### SUMMARY

In accordance with the present teachings, an edge area substrate processing method and apparatus provides advantages over the aforementioned processing methods and systems. An aspect of the present teachings is directed to a method and apparatus for dry chemical processing at atmospheric pressure, the edge area of a substrate in isolation from the remainder of the substrate According to the present teachings, a method for centering a wafer on a rotatable chuck is provided. The method includes the steps of positioning a wafer adjacent to a micrometer. The wafer is then rotated and a plurality of wafer edge locations and rotational increments are measured. A center offset value for the value of the wafer center with respect to a chuck is calculated. The wafer is then moved with respect to a center position of the chuck.

In one embodiment, moving the wafer to a center position is positioning the wafer on a fixed support and rotating a portion of the multi-axis support device with respect to the wafer and re-engaging the wafer. Additionally, moving the wafer center can include translating the center of a support device chuck to the center of the wafer can be used.

In another embodiment, a method for centering a wafer on a rotatable chuck is provided. The method includes the steps of positioning a wafer adjacent to an edge measurement device. The wafer is then rotated and a plurality of wafer edge locations and rotational increments are measured. A wafer center is calculated using a least-squares fitting routine.

In another embodiment, a method for centering a wafer on a rotatable chuck is provided. The method includes the steps of positioning a wafer adjacent to a micrometer. The wafer is then rotated and a plurality of wafer edge locations and rotational increments are measured. The center of the wafer is calculated. The location of the multi-axis support with respect to the wafer is adjusted.

In another embodiment, moving the wafer to a center position is positioning the wafer on a fixed support and rotating a portion of the multi-axis support device with respect to the wafer and engaging the wafer. Additionally, the system adjusts the location of the wafer with respect to the multi-axis support if the center of the wafer is at a distance greater than a predetermined distance from a chuck center.

Further areas of applicability of the present invention will become apparent from the detailed description provided hereinafter. It should be understood that the detailed description and specific examples, while indicating the preferred embodiment of the invention, are intended for purposes of illustration only and are not intended to limit the scope of the invention.

### DRAWINGS

The drawings described herein are for illustration purposes only and are not intended to limit the scope of the present disclosure in any way.

FIGS. 1A-1C are cross-sectional schematics depicting a system for concentric wafer process application;

FIG. 2 is a top schematic depicting exchange/centering and processing positions of a wafer within a process chamber;

FIG. 3 is a side schematic depicting exchange/centering and processing positions of a wafer within a process chamber;

FIG. 4A depicts a side sectional view of a labyrinth seal assembly in relationship to a processing chamber and chuck assembly;

FIG. 4B depicts a top sectional view of a labyrinth seal assembly in relationship to a processing chamber and chuck assembly;

FIG. 5 represents a side sectional view of the isolator chamber shown in FIG. 1A;

FIG. 6A depicts a top view of a plurality of nozzle bodies relative to an edge of a wafer;

FIGS. 6B through 6F represent side views depicting bevel nozzles at a wafer bevel region;

FIGS. 7 through 8G represent cross-sectional views of pre and post processed wafers;

FIGS. 9A-9C represent side views depicting alternate nozzle configurations at a wafer bevel region;

FIG. 10 depicts a schematic view of a misaligned wafer at two different rotational positions relative to an aligned position within the exchange/centering apparatus;

FIGS. 11-12B detail an optical inspection system of the present disclosure;

FIG. 13 represents an exploded cross sectional view of a portion of the processing chamber and the isolator assembly shown in FIG. 1;

FIGS. 14A and 14B are sectional views of the sealing mechanism of the system shown in FIG. 3;

FIG. 15 represents a perspective sectional view of the sealing mechanism shown in FIGS. 14A and 14B;

FIGS. 16A and 16B represent cross sectional views of the system shown in FIG. 3;

FIGS. 17A-17C represent an exploded view of the isolator assembly shown in FIG. 13;

FIGS. 18A and 18B represent perspective views of the nozzle assembly of FIG. 17A;

FIGS. 19A and 19B represent a nozzle usable in the nozzle assembly of FIGS. 18A and 18B;

FIGS. 20A and 20B represent an alternate nozzle usable in the nozzle assembly of FIGS. 18A and 18B;

FIGS. 21A and 21B represent an alternate nozzle assembly;

FIGS. 22a and 22b represent nozzle subplates as shown in FIG. 21A and 21B;

FIGS. 23A and 23B represent cross sectional views of an alternate igniter assembly according to the present teachings;

FIGS. 24 through 25B represent top and side views of the igniter and nozzle assemblies;

FIG. 26 represents a perspective view of an alternate clean ignition assembly;

FIG. 27 represents a top view of a flame sense system for use in the wafer processing system according to FIG. 1A; and

FIGS. 28 and 29 represent responses detected by the flame sense system.

### DETAILED DESCRIPTION

The following description is merely exemplary in nature and is not intended to limit the present disclosure, application, or uses.

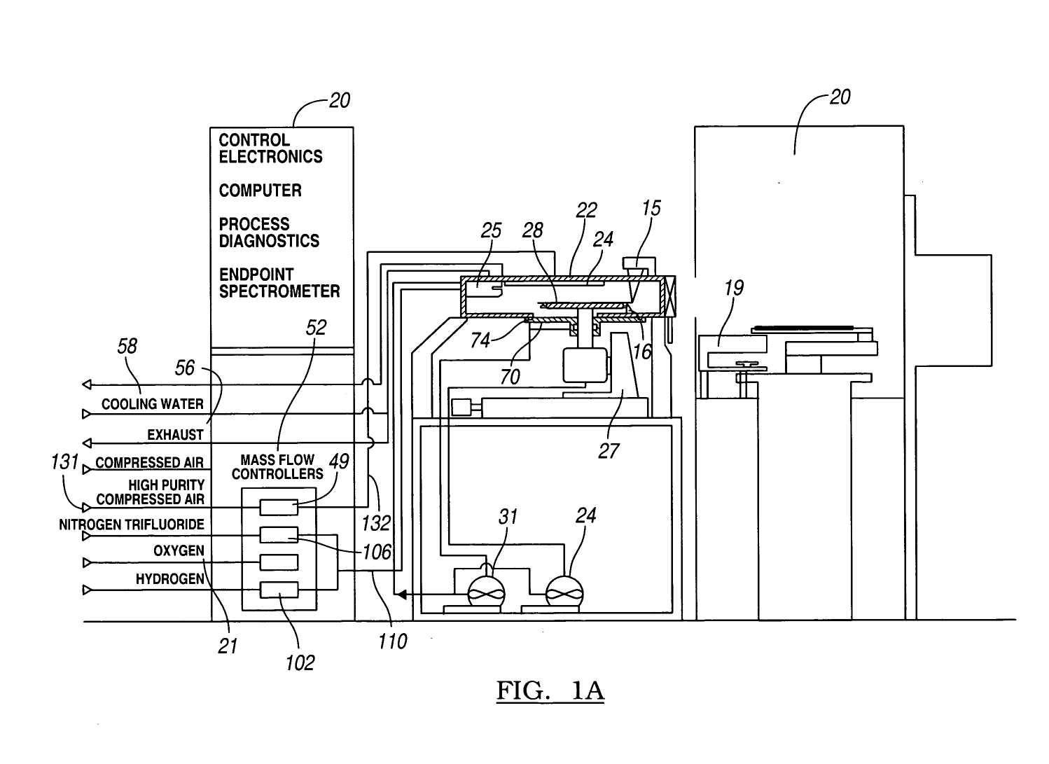

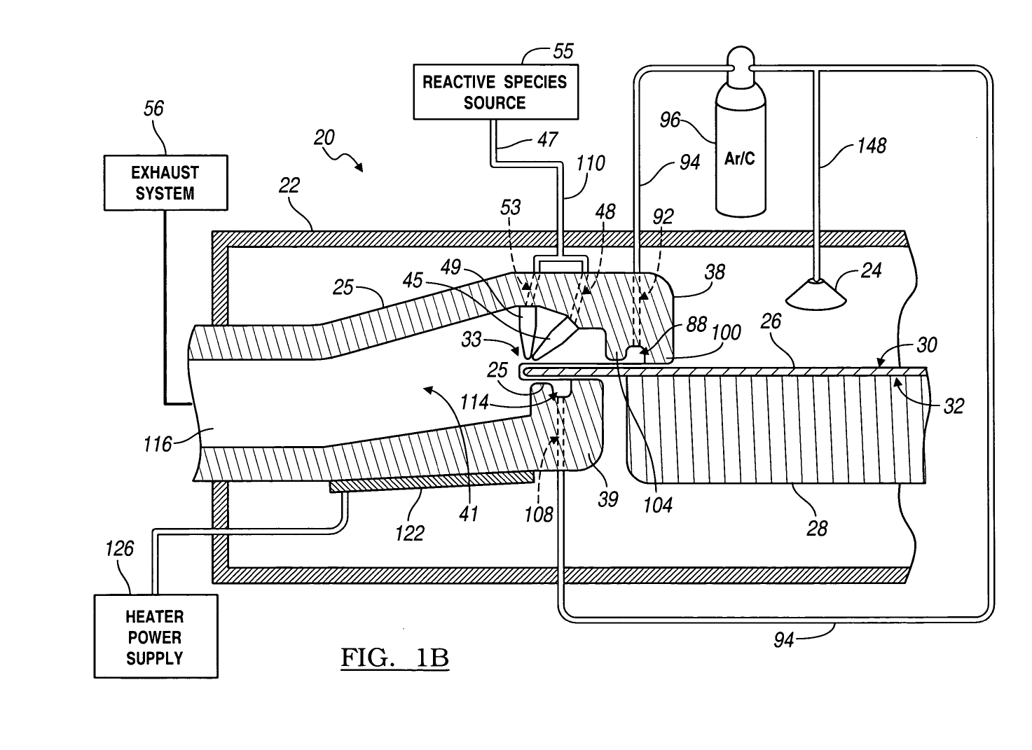

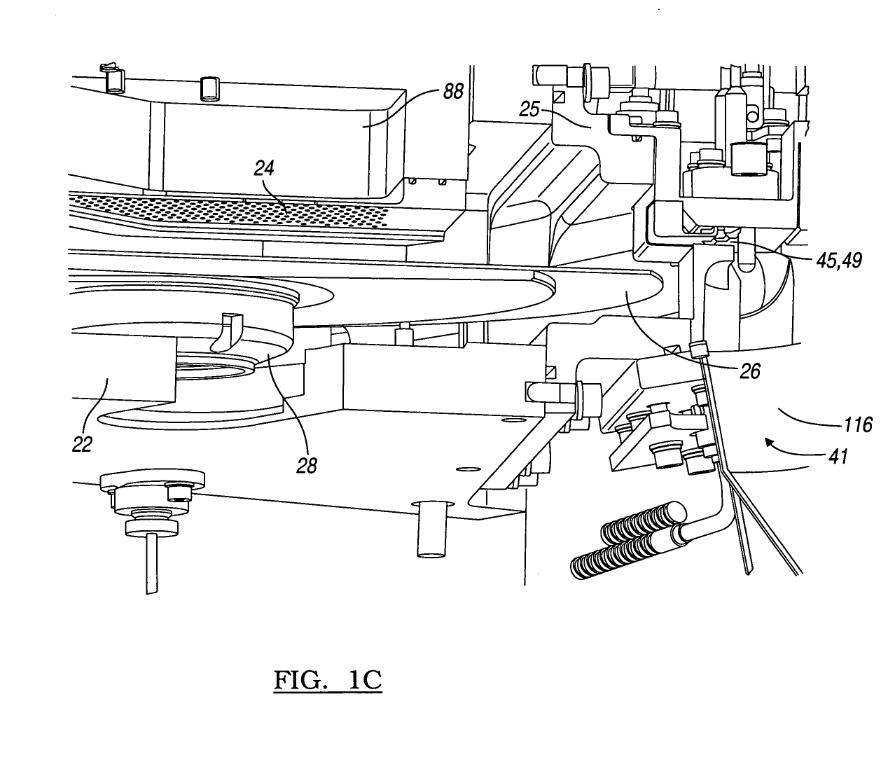

FIGS. 1A and 1B represent a system level view of the components and methods required to achieve concentric process application utilizing a wafer processing system according to the teachings herein. One example relates to selectively applying chemistry to the near edge region of a wafer. Other possibly applicable methods and apparatus are disclosed in U.S. patent application Ser. Nos. 11/230,261 and 11/417,297 which are both incorporated by reference.

Central to the present disclosure's near edge film removal technology is the ability to apply reactive gas to a wafer in a highly concentric and precise fashion. Process application is typically sensitive to wafer or substrate eccentricity variation in the range of 50 to 100 μm. Multiple subsystems are required to achieve this type of process application.

FIG. 1A shows a system level schematic view of the overall system for concentric wafer process application. The process chamber 22 contains the isolator 25 and diffuser 24 for controlled application of reactive gas to the near edge wafer region. The R-Z-θ or xyz-θ wafer movement alignment module or system 27 is shown in the wafer load position where the laser micrometer 15 measures the trajectory of the wafer edge during the centering routine. Lift pins 16 are also shown.

The equipment front end module 17 contains a robot and the pre-aligner station 19. Wafers are processed from a front opening unified pod. The utility cabinet 20 contains control electronics, computer(s), endpoint equipment, gas delivery equipment and other facilities interconnects. Process gases 21 are connected to the module and flow regulated by appropriate mass flow controllers (MFC's) 52. Other facilities connections such as exhaust 56 and cooling water 58 are also connected.

Referring generally to FIGS. 1A-9C, an embodiment of the wafer edge area processing system 20 (the “system”) of the invention has a processing chamber 22 with an isolator 25 and wafer alignment module 27 with associated wafer chuck 28 disposed therein. A wafer 26 is retained on top of the wafer chuck 28 with the wafer 26 having a top surface 30, bottom surface 32, and edge area 33 (including edge and near edge as shown by lighter line proximal to edge) that surrounds the radial perimeter of the wafer 26. The isolator 25 has an upper section 38 extending over a portion of the top surface 30 of the wafer 26 and a lower section 39 extending over a portion of the bottom surface 32 of the wafer 26. The inside of the isolator 25 has a processing area for processing the edge area 33 of the wafer 26. The processing area leads into an exhaust plenum 41 connected to an exhaust system 56 for exhausting gases, process byproducts, and condensation.

Disposed within the upper section 38 of the isolator 25 are a first nozzle 45 and a second nozzle 49. Both nozzles are configured to emit a directed flow of reactive species towards the edge area 33 of the wafer 26. First nozzle 45 is offset from an axis perpendicular to a plane that is common with the top surface 30 of the wafer 26 (the “wafer plane”). First nozzle 45 is pointed towards the top surface 30 at an angle of 80°±5° relative to the wafer plane. Second nozzle 49 is offset by an angle of 45°±5° to the wafer plane. Second nozzle 49 is also offset by ˜15° from a plane perpendicular to the wafer plane that runs through the center of the isolator 25 and center of the wafer 26.

First nozzle 45 is connected to a first channel 48 disposed in the upper section 38. First channel 48 leads to a gas line 47. Second nozzle 49 is connected to a second channel 53 disposed in the upper section 38. Second channel 53 leads to the gas line 47. First nozzle 45 and second nozzles 49 are connected via the gas line 47 to a reactive gas species source. Optionally, the first and second channels 48 and 53 can be coupled to sources having differing chemistry.

First nozzle 45 is positioned for bevel and crown processing at a distance of 0.1 to 0.5 mm from the edge of the wafer 26 and 1.3 to 1.8 mm distance from the top surface 30 of the wafer 26. Second nozzle 49 is positioned 0.5 to 3.0 mm in from the edge of the wafer 26 and 0.6 to 1.1 mm distance from the top surface 30 of the wafer 26. Radial position of the nozzles and distance from the wafer surface is dependent upon desired edge exclusion area and is also process and film dependent.

Reactive gas species source either provides a reactive gas species or component reactants for forming the reactive gas species. Reactive gas species can be generated via near atmospheric pressure techniques. This includes near atmospheric capacitively coupled plasma source (i.e., APJET), as described in U.S. Pat. No. 5,961,772, incorporated herein by reference or inductively coupled plasma discharge (i.e., ICP torch), as described in U.S. Pat. No. 6,660,177, incorporated herein by reference or combustion flame.

Spontaneous etchants, for example F₂, O₃, or HF can also be used. Advantageously, none of these reactive species techniques produce ion bombardment characteristic of an ionic plasma thus minimizing surface and device damage potential. Further, although envisioned, none of these techniques requires a vacuum chamber together with associated equipment.

An upper purge plenum 88 disposed in the upper section 38 extends at or near the edge of the top surface of the wafer 26, above and across an area of the wafer to be processed to at or near another edge of the top surface 30 of the wafer 26. The upper purge plenum 88 is ˜3.0 mm wide and extends for a total path length of ˜37.5 mm. The upper purge plenum 88 is part of a tuned flow system which prevents reactive gas migration out of the processing area.

The upper purge plenum 88 is connected to a first purge channel 92 that is connected to a purge gas source 96 via a purge gas line 94. The purge gas source 96 supplies an inert gas, for example, argon that is fed via the first purge channel 92 into the upper purge plenum 88. Alternatively, the upper purge plenum 88 can provide CDA or oxygen containing gas, which augments the reaction of the reactive gas.

The use of oxygen containing gas allows the reaction of un-reacted H₂. This also compensates for extreme length limitations and allows for a higher volume fraction of NF₃. The increased NF₃ volume fraction leads to enhanced etched rates as well as an enhancement of throughput. Although one purge channel is seen disposed in the upper section 38 of the isolator 25, more than one channel may be present for directing a flow of purge gas into the upper purge plenum 88. Purge channels have an inside diameter of 2.00 mm. The flow of purge gas into the upper purge plenum 88 creates a pressure differential in the area of the top surface 30 surrounded by the upper purge plenum 88 resulting in a barrier between the top surface 30 and the edge area 33 of the wafer 26 being processed.

The upper purge plenum 88 is separated from the top surface 30 of the wafer 26 by an inside baffle 100. Inside baffle 100 follows along the inside perimeter of the upper purge plenum 88 and is separated from the wafer 26 by a gap of 0.30 to 0.80 mm. An outside baffle 104 follows along the outside perimeter of the upper purge plenum 88 and is separated from the wafer 26 by a gap of 0.50 to 1.10 mm. As seen, outside baffle 104 is wider and closer to the top surface 30 of the wafer 26 than the inside baffle 100. This facilitates forming a pressure induced barrier around the in-process portion of the wafer 26 by creating a pressure differential biasing a flow of a purge gas in a direction across inside baffle 100 into the processing area of the isolator 25.

A second purge channel 108 is disposed in the lower section 39 of the isolator 25. This is connected by the purge gas line 94 to the purge gas source 96. Second purge channel 108 is for feeding purge gas to a lower purge plenum 114. Similarly to the upper purge plenum 88, the lower purge plenum 114 extends from at or near the edge area 33 of the wafer 26 below and across the bottom surface 32 to at or near another location of the edge of the wafer 26. Similarly to the upper purge plenum 88, the lower purge plenum 114 is disposed between a lower inside baffle 112 and a lower outside baffle 118. The lower purge plenum 114 together with the lower inside baffle 112 and lower outside baffle 118 bias a flow of purge gas in a direction across the lower inside baffle 112 and across the bottom surface 32.

Wafer chuck 28 is movable in r-θ-z or xyz-θ directions, using module 27, for positioning the wafer 26 and rotating it within a slot of the isolator 25 defined between the upper section 38 and lower section 39. Alternatively, the isolator 25 structure can also be moved in r with the chuck moving in θ and z. Once in position the distance between each side of the wafer 26 and the upper section 38 or lower section 39 is 0.30 to 0.80 mm. The slot open area without a wafer 26 is 124.20 to 216.20 mm². The slot open area with a wafer 26 present is 55.20 to 147.20 mm². The exhaust slot width is 93.0 mm.

A gas diffuser 24 extends into the processing chamber 22 providing a flow of inert or oxygen containing gas to the processing chamber 22. The gas diffuser 24 is typically of the shower head type design and is connected via a diffuser 24 gas line 148 to the purge gas source 96.

The exhaust plenum 41 together with the exhaust system 56 are an additional part of the tuned flow system which prevent reactive gas migration out of the processing area. Exhaust system 56 creates a negative pressure in the exhaust plenum 41 that draws active species gases together with the inert gas, processed byproducts, and condensation away from the processing area and prevents migration of these gases into the device area of the wafer 26.

A heater element 122 is connected by a heater line to a heater power supply 126. The heater element 122 heats the isolator 25 and to a lesser extent, the wafer 26. Heating the isolator 25 is desirable to prevent condensation of gases that can be corrosive to the isolator 25 and potentially introduce contamination into the processing area.

The nozzles of the edge area processing system 20, including the first nozzle 45 and second nozzle 49 are made of sapphire. Sapphire is advantageously non-reactive to the chemistries used in substrate processing. This is desirable since the processing of semiconductor substrates requires trace material contamination analysis at the parts per million level with acceptable addition to the substrate being less than approximately 10¹⁰ atoms/cm². Further, particle additions to the substrate should be zero for sizes greater than approximately 0.1 micron.

It is also, in many situations, desirable to achieve a laminar gas flow from the nozzles. This requires setting the aspect ratio of the nozzle at greater than or equal to 10× length to diameter. With some reactive gases, aspect ratios of greater than 40:1 or preferably 80:1 are desirable. Nozzle inside diameters are around 0.254 to 0.279 mm which requires a uniform smooth nozzle bore length of approximately 2.50 mm.

The isolator 25 nozzles, including the first nozzle 45 and second nozzle 49, while described as angled relative to the wafer plane at ˜80 degrees and ˜45 degrees, respectively, can advantageously be angled in a different direction relative to the wafer plane in order to facilitate processing including etching or deposition of a thin film.

In operation, a wafer 26 is centered on the wafer chuck 28 and then the wafer chuck 28 positions the wafer 26 in the slot of the isolator 25 between the upper section 38 and the lower section 39 for processing. The movement system 27 rotates wafer chuck 28, and thus the wafer 26.

Inert gas or CDA is allowed to flow into the upper purge plenum 88 and lower purge plenum 114 from the purge gas source 96. The inert gas or CDA flows into the upper purge plenum 88 and lower purge plenum 114 at a rate of 100 sccm to 8,000 sccm. Inert gas or CDA is also allowed to flow into the processing chamber 22 through the gas diffuser 24. This gas flows into the processing chamber 22 at a rate of 500 sccm to 10,000 sccm.

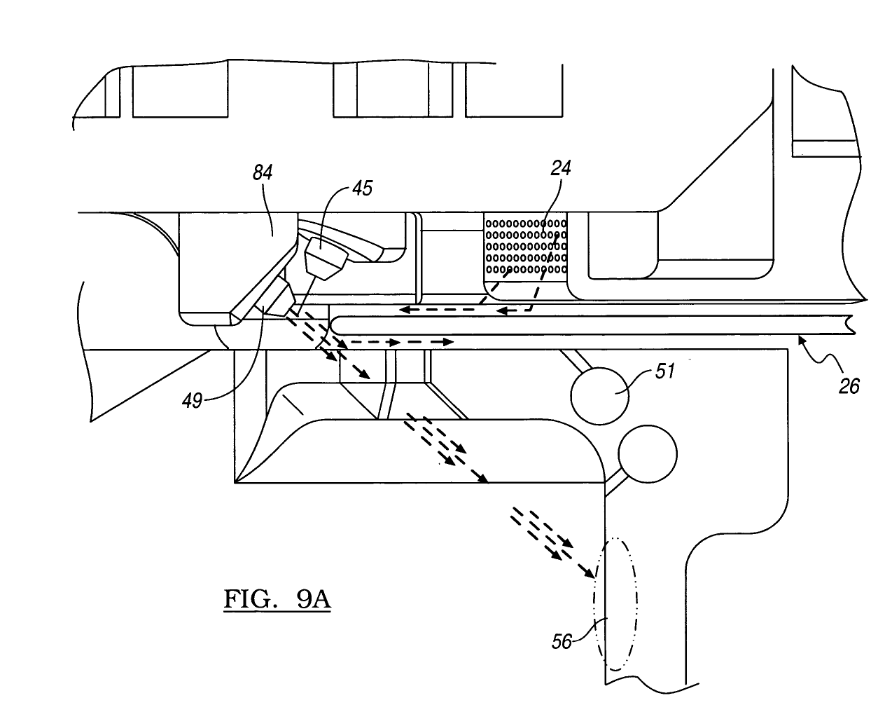

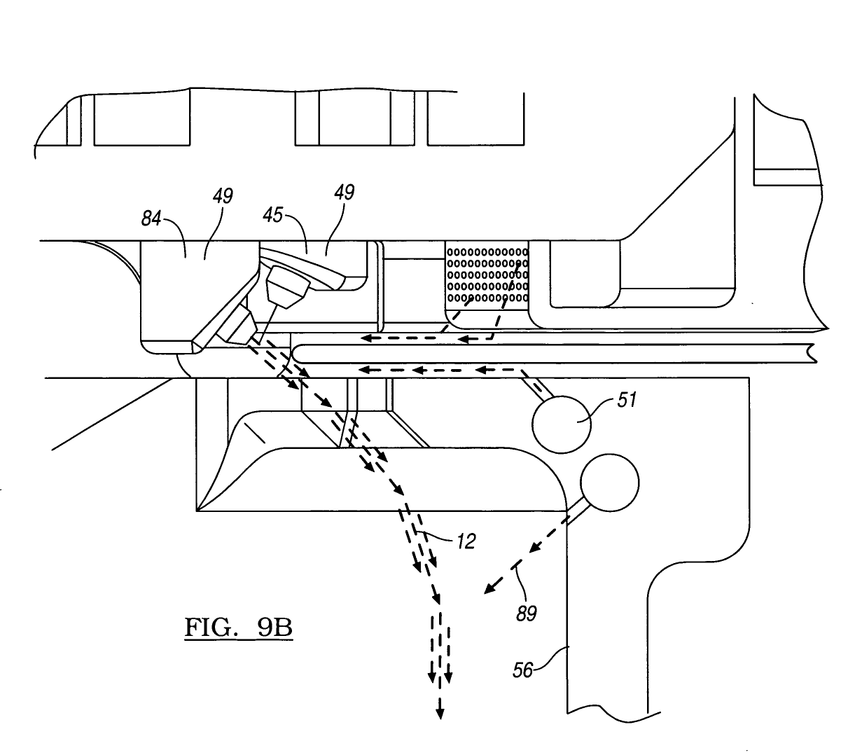

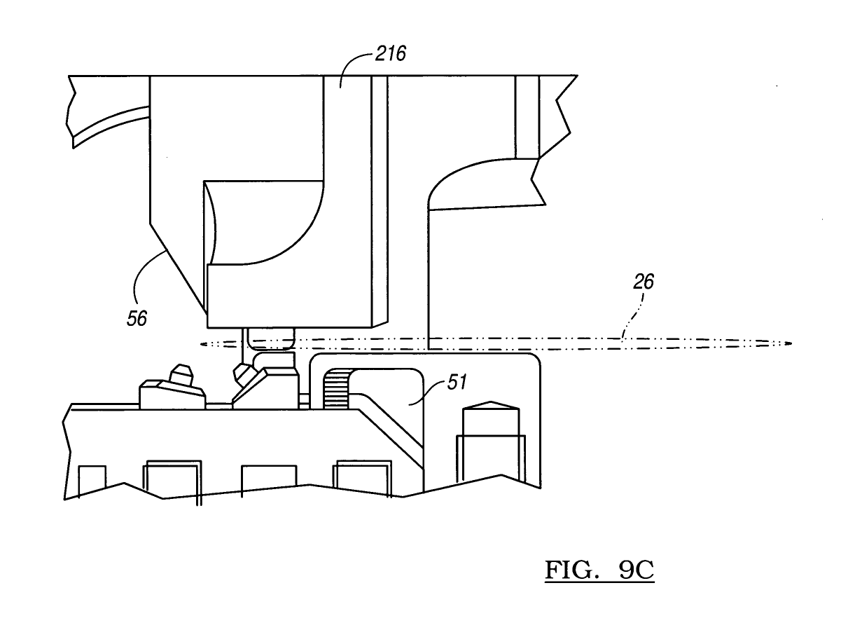

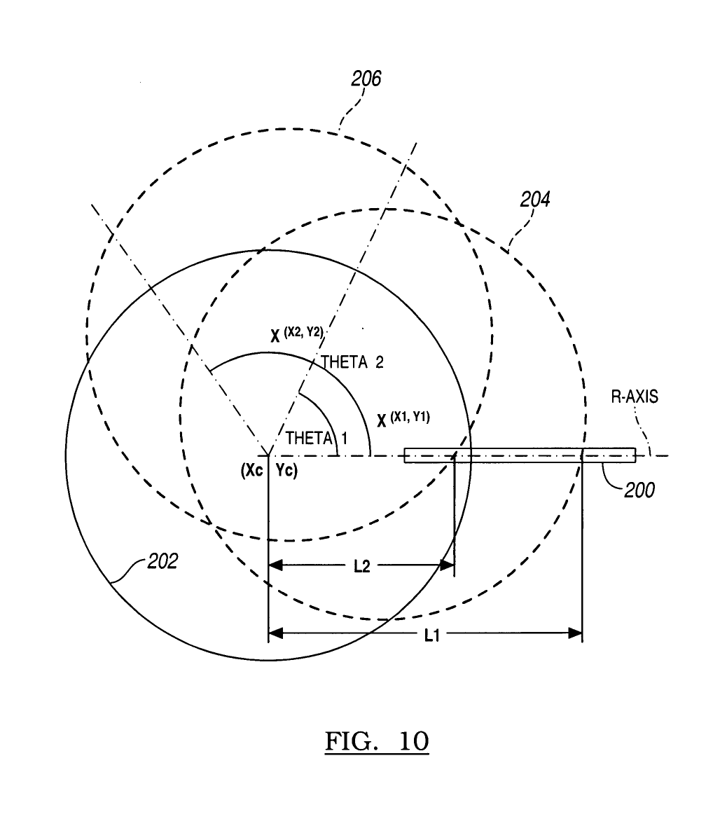

The exhaust system 56 is activated to draw gases and process byproducts including condensation through the exhaust plenum 41. Next, reactive species 130 emit from first nozzle 45 and second nozzle 49. The igniter power supply 126 energizes the clean igniter system 78 and the first gas line 93 and second gas line 98 are opened to allow a flow of hydrogen and nitrogen trifluoride gases into the nozzle assembly 84 and through the four nozzles 84. The gas mixture is frequently different during the ignition stage. The igniter nozzle uses H₂ and O₂ only at higher total flow rates than the processing nozzles 45, 49. Typically, the initiator nozzle uses approximately 800 sccm H₂ and 200 sccm. The process nozzles typically ignite with a Lo NF₃fraction. Typically about 20 sccm max. Reactive species (or gases in the case of a combustion flame) flow through the nozzles at a rate of between 200 and 800 sccm and preferably between 375 sccm to 475 sccm. The reactive species 130 impinge upon the edge area 33 of the wafer 26 as the wafer 26 rotates. The reactive species 130 react with a thin film or contaminant in the edge area 33 of the wafer 26 resulting in a reactant byproduct 66. Alternate nozzle configurations are envisioned. For example, referring briefly to FIGS. 9A-9C, the position of the first processing nozzle 45 and second processing nozzle 42 includes the reactive species 130 to “wrap around” the top bevel, crown, bottom bevel of the wafer 26.

Heater 122 is energized to heat the wafer top surface 30. This optional step is intended to prevent vapor produced as a byproduct of the chemical reaction, for example water vapor, from condensing on the wafer top surface 30. Condensation can be prevented by heating the wafer top surface 30 to a temperature at or above the boiling point for the reactant byproducts, for example heating the wafer top surface 30 above 100° C. to prevent the condensation of water. Alternatively, wafer 26 surface heating can be supplied via a heated substrate holder 82 or via infrared energy directed at the wafer perimeter, or via other heat sources such as a flame.

The reactive species 130 are prevented from passing out of the isolator 25 by the flow of inert gas working in concert with a pressure differential drawing gases into the exhaust plenum 41 and into the exhaust system 56. This inert gas forms a pressurized barrier in the upper purge plenum 88 and lower purge plenum 114 surrounding the in-process edge area of the wafer. The inside baffle member 61 in cooperation with the outside baffle member 63 biases the flow of insert gas towards the in-process area of the wafer 26. Reactant byproducts formed as a result of the reactive species 130 reacting with a thin film on the wafer 26 surface are drawn away from the in-process area of the wafer 26 into the exhaust plenum 41. Thus, advantageously, reactive species 130 and reactive byproducts 142 are confined to the edge area of the wafer 26 and prevented from migration into other areas of the wafer 26 that may damage wafer component devices. In addition, the pressure differential induced by the exhaust plenum 41 further biases gas flow away from the central portion of the wafer 26.

As the wafer 26 rotates either the wafer chuck 28 translates with respect to the nozzle assembly 84 and the combustion flame across the wafer top surface 30. As a result a desired section of the wafer top surface 30 is processed. Processing includes the removal of a thin film, for example, silicon dioxide or tantalum as described above in relation to the substrate processing method.

After the wafer is processed, the first gas controller 102 and second gas controller 106 are closed. Simultaneously, the fourth gas controller 49 is opened to allow a flow of argon gas or CDA into the edge-type nozzle assembly 84 and through the first and second nozzles 45, 49 to “blow out” the combustion flame. The controller 140 additionally allows blow off of the nozzles if EMO or a power failure occurs. Additionally, the controller 52 can extinguish the flames upon low gas delivery pressure, if the enclosure is opened, or if there is a loss of control air. Also coupled to the controllers are a plurality of H₂ sensors which will shut off the system or signal an alarm should the H₂ level in the chamber 22 be above a predetermined level. The wafer 26 may be removed after the chamber 22 is evacuated of process gases and byproducts.

Processing of the edge area 33 of the entire wafer may be accomplished with a single rotation of the wafer 26. Alternatively, more than one rotation may occur and more than one process may be performed including deposition and etching. After the flow of reactive species is stopped a flow of the inert gas continues until the processing chamber 22 is sufficiently evacuated of other gases and condensations. Then, the heater element 122 is turned off and the flow of inert or CDA gas from the purge gas source 96 is stopped and the wafer 26 is removed and replaced with another wafer for processing.

The described system 20 and associated method for using the system is suitable for etching of target thin films. This includes, but is not necessarily limited to, tantalum and tantalum nitride; inter-layer dielectrics; backside polymers; and photoresist edge bead.

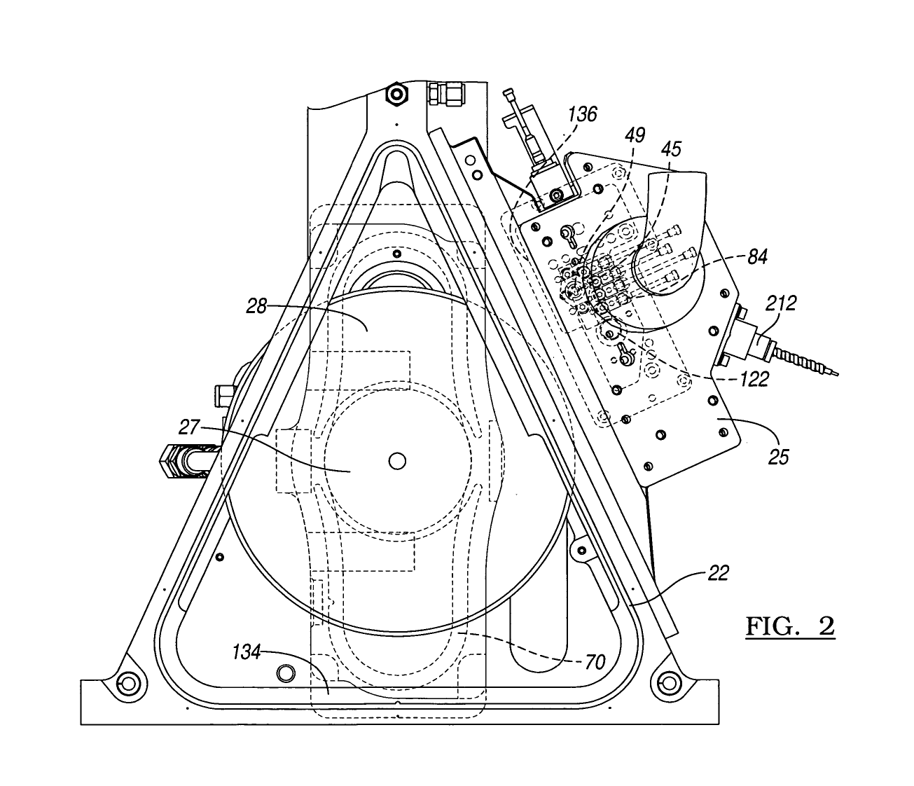

FIG. 2 represents a top view of the system shown in FIG. 1A. Shown is the isolator 25 with associated nozzle assembly 84, Flame sense system 212, and heater 122. Also shown is the movement system 27 with labyrinth seal 70 and measuring micrometer 15. The wafer 26 is moved from the installation position 134 to the processing position 136 by translation of the chuck 28.

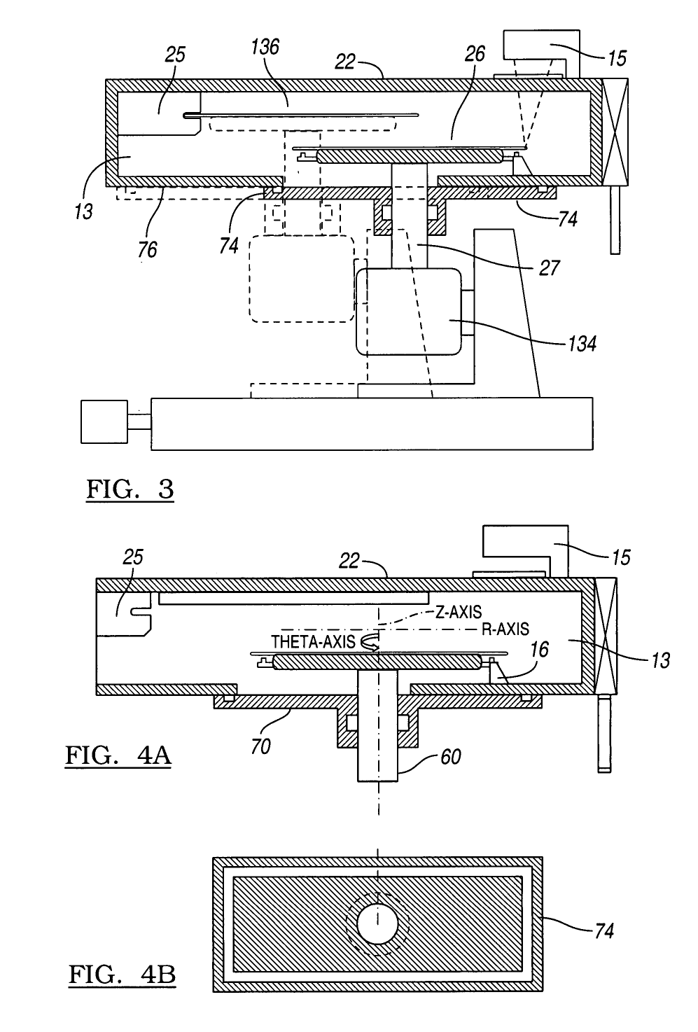

FIG. 3 shows exchange/centering 134 and processing 136 positions of the R-Z-θ stage. Relationship of the labyrinth seal 70 to the process chamber 22 and chuck spindle 60 are also shown. Vacuum for labyrinth seal 70 operation is supplied by a vacuum pump 31 or other appropriate vacuum generator. Computer control of the vacuum level can be integrated using a throttle valve, electronic mass flow, or pressure controller in conjunction with a venturi type vacuum generator. Vacuum for the wafer chuck clamping force is also supplied by a vacuum pump 31. Pressure differential was found to be the most critical parameter determining function of the seal. Gap distance between 120 μm and 500 μm between the sealing plate 74 and the bottom surface 76 of the process chamber 22 was also found to be important.

The translational ‘R-axis’ gap and the ‘Z-θ axis’ gap are shown in FIG. 3. When operated using proper conditions, the helium leak rate of the seal is <1.0×10⁻⁶ atm-cc/s. This leak rate is equivalent to that of an o-ring sealed interface. It must be noted that o-ring interfaces have been found to be unacceptable inasmuch as they generate undesirable particulate. Gap values in the range of 127 μm to 508 μm were tested and found functional provided the proper pressure differential was maintained. Mass flow magnitude increases dramatically with increasing gap placing a practical upper limit of 254 μm. Machining tolerances set the practical lower gap limit at 127 μm.

A minimum pressure differential between the seal exhaust ports, and the process chamber 22 was found to be −2 water column inches. Larger differential pressure values can be used and a practical upper limit is not known. Pressure differential between the process chamber and atmosphere should be at least −0.4 water column inches. This results in a seal exhaust to atmosphere pressure differential of at least −2.4 water column inches.

FIGS. 4A-4B show side and top views of the labyrinth seal 70 assembly in relationship to the chamber 22 and movement system 27. Vacuum channel sealing the traverse (R-axis) motion is shown along with the channel 79 sealing vertical (Z-axis) and rotary (θ-axis) motion components. Each vacuum channel is connected via tubing to an independently controlled vacuum generator or pump. Note that the labyrinth seal plate 74 is machined from 304 or 316 series stainless steel. Corrosion resistance is enhanced by a post machining metal finishing process consisting of electro-polishing and passivation.

Referring again to FIGS. 1-9B, an embodiment of a substrate processing method 10 of the invention employs a combustion flame 12 formed of an ignited combustion of gaseous reactants 14 including hydrogen (H₂) and nitrogen trifluoride (NF₃, as a non-oxygen “oxidizer”) in an oxygen enhanced environment 13. Although CDA is illustrated, other oxygen containing gases are suitable. A mixture of gaseous reactants passes through a torch nozzle 45 before igniting into combustion flame 12. Combustion flame 12 impinges upon a substrate surface 18.

Gaseous reactants react in combustion flame to form gaseous hydrogen fluoride (HF) (a reactive species) and gaseous nitrogen (N₂) effluents. The following chemical equation describes the production of gaseous hydrogen fluoride and gaseous nitrogen from gaseous reactants based on a stoichiometric mixture (a 3:2 molar ratio):
3H₂ (gas)+2NF₃ (gas)→6HF (gas)+N₂ (gas)

Advantageously, this reaction is performed substantially at atmospheric pressure. This allows for use of viscous (rather than molecular). flow properties to precisely treat portions of the substrate surface 18 and minimize exposure of other substrate areas to the reactive process. Although a 3:2 molar ratio is described higher or lower ratios may be used depending on the desired result.

Further, this reaction is not induced by an ion producing field consistent with a plasma. It is believed that a plasma is a collection of charged particles where the long-range electromagnetic fields set up collectively by the charged particles have an important effect on the particles' behavior. It is also believed that the combustion flame 12 has substantially no ionic species present. As a result, there is no risk of ionic damage to the substrate.

Substantial heat is generated from the exothermic chemical reaction of H₂ and NF₃. This effect allows a small volume of highly reactive species in the form of HF to be generated due to the amount of energy represented by the resultant temperature. Elevated temperature in turn substantially increases reaction rates which results in higher etch rates. The result is higher process throughput.

A silicon dioxide thin film can be etched by the gaseous hydrogen fluoride according to the following overall reaction:
4HF (gas)+SiO₂ (solid)→SiF₄ (gas)+2H₂O (gas)
Gaseous silicon tetrafluoride and water vapor leave the surface of the silicon dioxide thin film. Advantageously, this reaction provides for a change of silicon dioxide thin film from a solid to a gas byproduct that can be easily evacuated.

Gaseous hydrogen fluoride will also etch a substrate surface of silicon. Silicon etching follows the following overall reaction:
4HF (gas)+Si (solid)→SiF₄(gas)+2H₂ (gas)
In this reaction, gaseous silicon tetrafluoride and gaseous hydrogen leave the silicon substrate surface. This reaction provides for a change of silicon on the substrate surface from a solid to a gas byproduct that can be evacuated.

Similarly, etching of a tantalum thin film follows the following overall reaction:
10HF (gas)+2Ta (solid)→2TaF₅ (gas)+5H₂ (gas)
In this reaction, gaseous tantalum pentafluoride and gaseous hydrogen leave the tantalum substrate surface. This reaction provides for a change of the tantalum on the substrate surface from a solid to a gas byproduct that can be evacuated. For this reaction, preheating of the wafer using an O₂+H₂ flame is desirable to prevent the condensation of reaction products on the wafer.

Organic and polymer films can also be removed using the above described chemistry however selectivity issues to Si and SiO₂ may in some instances make this less desirable. The above chemistry for example can be used to etch SiO₂ over Si where etching of oxide is desirable but Si is not. Passivation of exposed Si to the etch chemistry can be promoted by first exposing an etch field to a hydrogen rich flame with oxygen. The etch field is then exposed to the combustion flame of H₂ and NF₃ where the oxide is etched.

Other desirable non-oxygen oxidizers for reaction with hydrogen in a combustion flame for substrate etching include fluoride (F₂), chlorine (Cl₂), and chlorine trifluoride (ClF₃). Hydrogen and fluoride react in a combustion flame as follows:
H₂ (gas)+F₂ (gas)→2HF (gas)
Similarly to the combustion flame of H₂ and NF₃ the resulting HF reactive species is a desirable etchant as described above.

Hydrogen and chlorine react in a combustion flame as follows:
H₂ (gas)+Cl₂ (gas)→2HCl (gas)

Hydrogen and chlorine trifluoride react in a combustion flame as follows:
4H₂ (gas)+2ClF₃ (gas)→6HF (gas)+2HCl (gas)

In both the proceeding combustion flame reactions, the resultant hydrogen chloride reactive species can be advantageously used for etching when materials not readily etched by fluorine are present in the film stack. This includes a film stack comprising aluminum. Hydrogen chloride as a reactive species etches aluminum as follows:
2Al (solid)+6HCl (gas)→2AlCl₃ (gas)+3H₂ (gas)

Hydrogen chloride etches silicon as follows:
Si (solid)+4HCl (gas)→SiCl₄ (gas)+2H₂ (gas)

Hydrogen chloride etches silicon oxide as follows:
SiO₂ (solid)+4HCl (gas) SiCl₄ (gas)+2 H₂O (vapor)

Chlorine trifluoride represents a hybrid etch chemistry where both fluorine and chlorine based etchant reactive species are produced. Often this compound is combined with another fluorine containing gas (such as NF₃ or CF₄) or with Cl₂ is used in varying ratios when multiple materials are present in the film stack, requiring both fluorine and chlorine based chemistry for removal.

The chemical equations shown above are a simplified view of the real reactions taking place within the combustion flame and on the substrate surface. The reaction chemistries occurring are quite complex resulting in intermediate and final reaction products.

A nozzle assembly 84 is held by a support member 46 over a wafer 26 retained on the substrate holder 82. Four nozzles 45 are disposed in the nozzle assembly 84. The nozzle assembly 84 is maintained at a distance of ˜1.5 mm from the wafer top surface 30 during processing.

A hydrogen gas source and nitrogen trifluoride gas source 55 are connected by a first gas line 48 and second gas line 53 through a first gas controller 102 and second gas controller 106 to a common mixing gas line 110 connected to the nozzle assembly 84 for combining and mixing H₂ and NF₃. An exhaust scoop 116 is adjacent to the substrate holder 82 for exhausting gases and reactant byproducts. The exhaust scoop is connected by a plenum 67 to a blower device 124. The exhaust scoop 116 draws gases and reactant byproducts out of the processing chamber 22 through the blower device 124.

In one embodiment, an argon gas source 96 is connected by a third gas line 132 through a third gas controller 49 to the processing chamber 22. In another embodiment, a CDA (clean dry air) or oxygen containing gas 72′ is connected by the third gas line 132 through a third gas controller 49 to the process wafer. The argon or CDA gas source 131 is also connected by a fourth gas line 134 through a fourth gas controller 49 to the common mixing gas line 110. An igniter assembly 78 positioned close to the nozzle assembly 84 is connected by wires 83 to an igniter power supply 126.

In operation, the robot unloads wafer from front opening unified pod (FOUP) and places the wafer on a pre-aligner 19. Once the pre-alignment routine is completed, the robot retrieves wafer from pre-aligner and places it into the chamber 22 on lift pins 16. Wafer chuck 28 moves up in z and lifts wafer 26 from lift pins 16 and rotates and positions the wafer edge to allow measurement using laser micrometer 15. Wafer center offset direction and magnitude is computed as described above. Wafer 26 is then rotated to align offset direction with the ‘r’ axis. The chuck 28 then descends in ‘z’ axis to return wafer to lift pins 16. The wafer movement system 27 moves chuck assembly increments in ‘r’ by the offset magnitude to center the chuck 28 with respect to the wafer 26. The movement system 27 then elevates in ‘z’ axis to lift wafer from lift pins 16. The chuck rotates and the edge position is re-measured to validate centering. The wafer is then ready for concentric process application as described above.

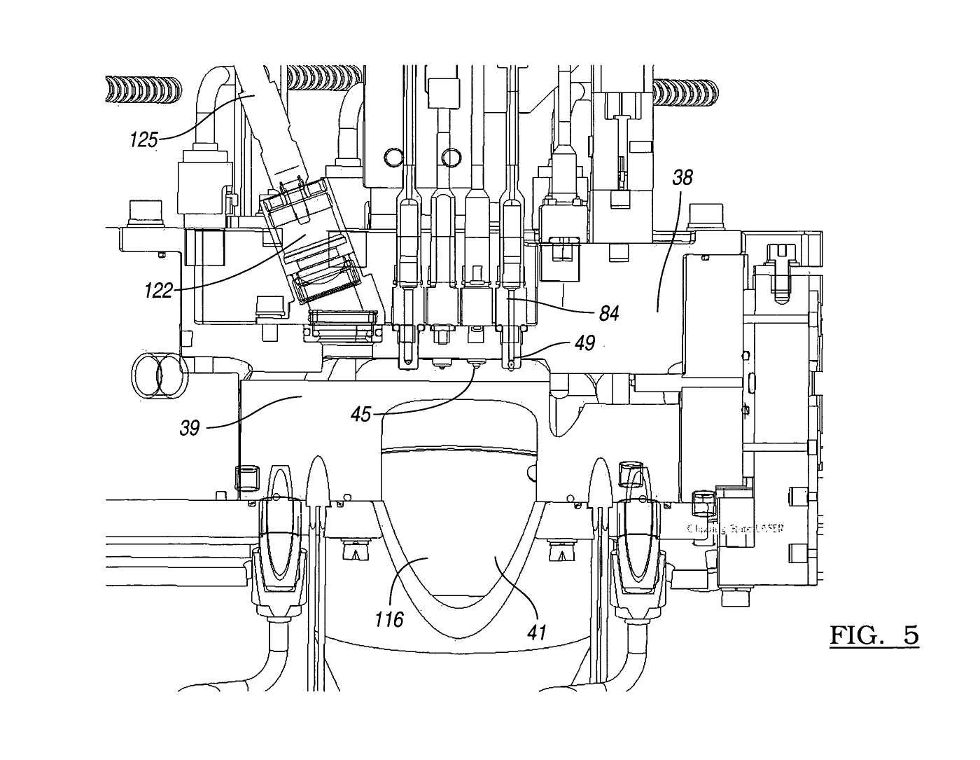

A heater 122 is positioned proximately to the area of the wafer 26 to be processed. The heater 122 (shown in FIG. 5) is an infrared (IR) or laser diode heater and is connected by a heater wire 87 to an IR heater power source 125. In a preferred embodiment the heater 122 is a fiber optic coupled laser diode array. A fiber optic cable assembly can be used in place of the heater 122. The fiber optic cable can deliver high power illumination originating in a laser diode assembly located remotely. Such illumination can perform heating of the wafer 26 such as discussed in United States Patent Application Publication No. 2005/0189329, titled “Laser Thermal Processing with Laser Diode Radiation” and incorporated herein by reference.

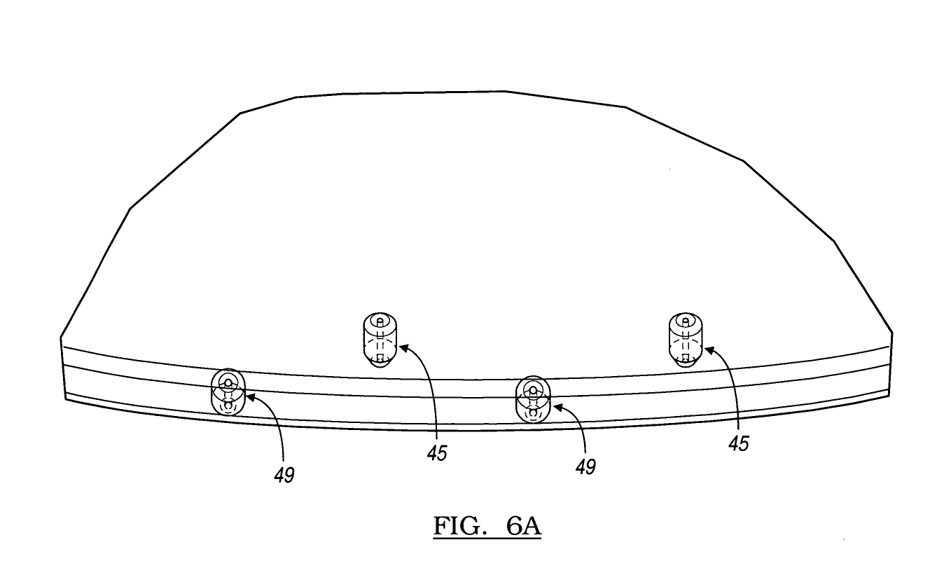

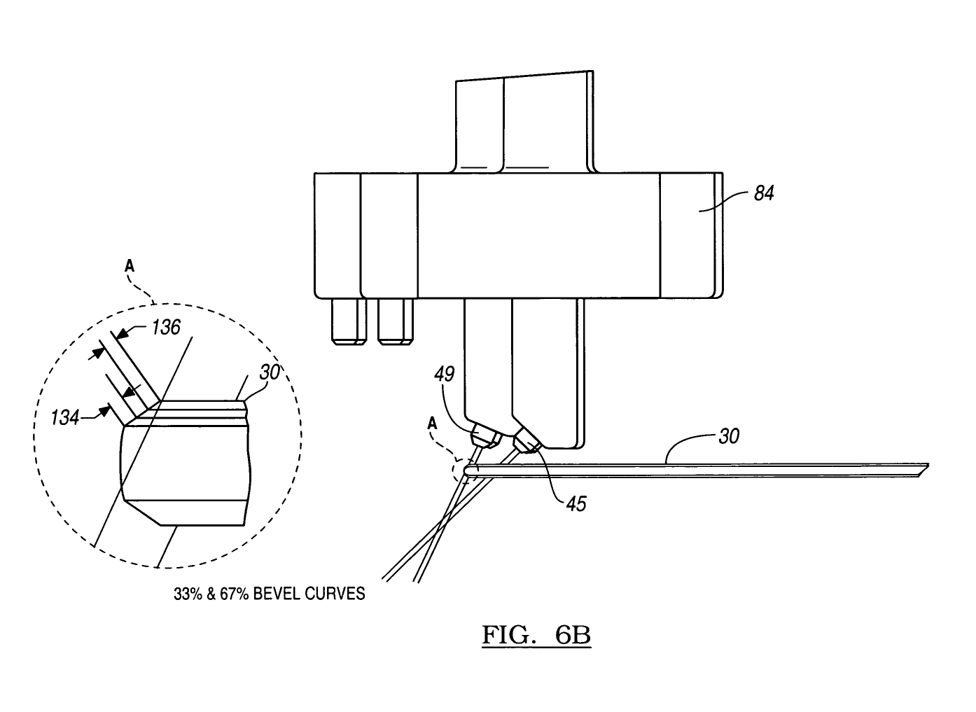

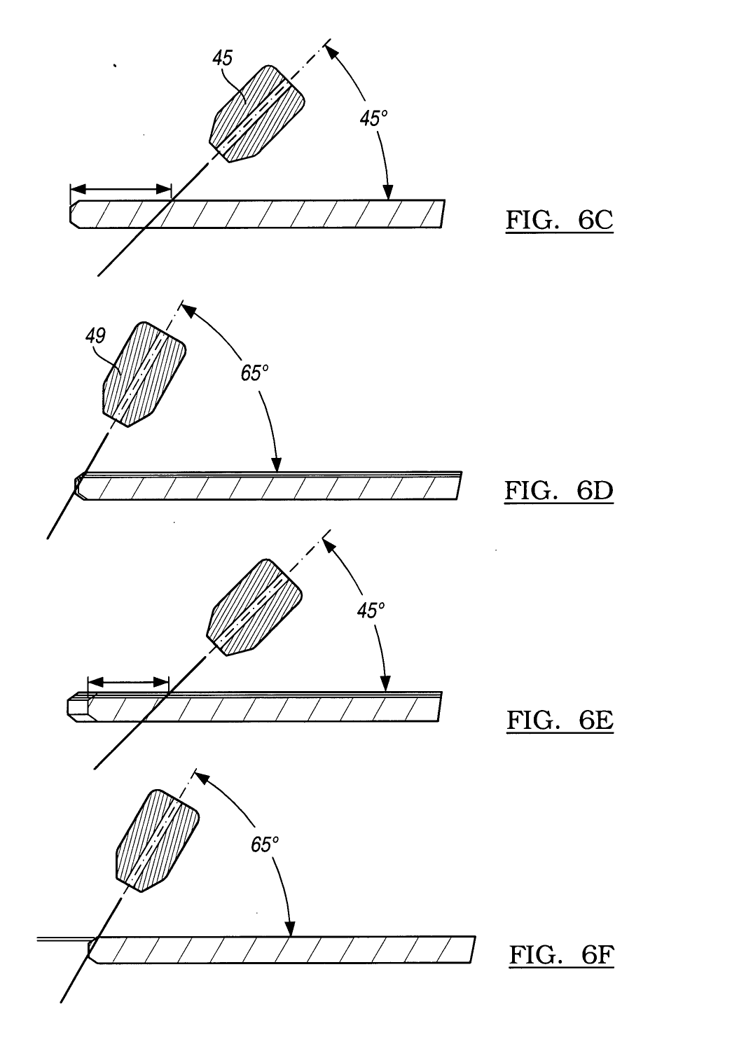

FIGS. 6A through 6F represent the nozzle 45, 49 positioning with respect the bevel edge of the wafer 26. By alternating the angles of the nozzles, proper coverage of the edge for particular region of the wafer edge can be accomplished. In this regard, depending upon the defects or films to be removed, various nozzle configurations are envisioned.

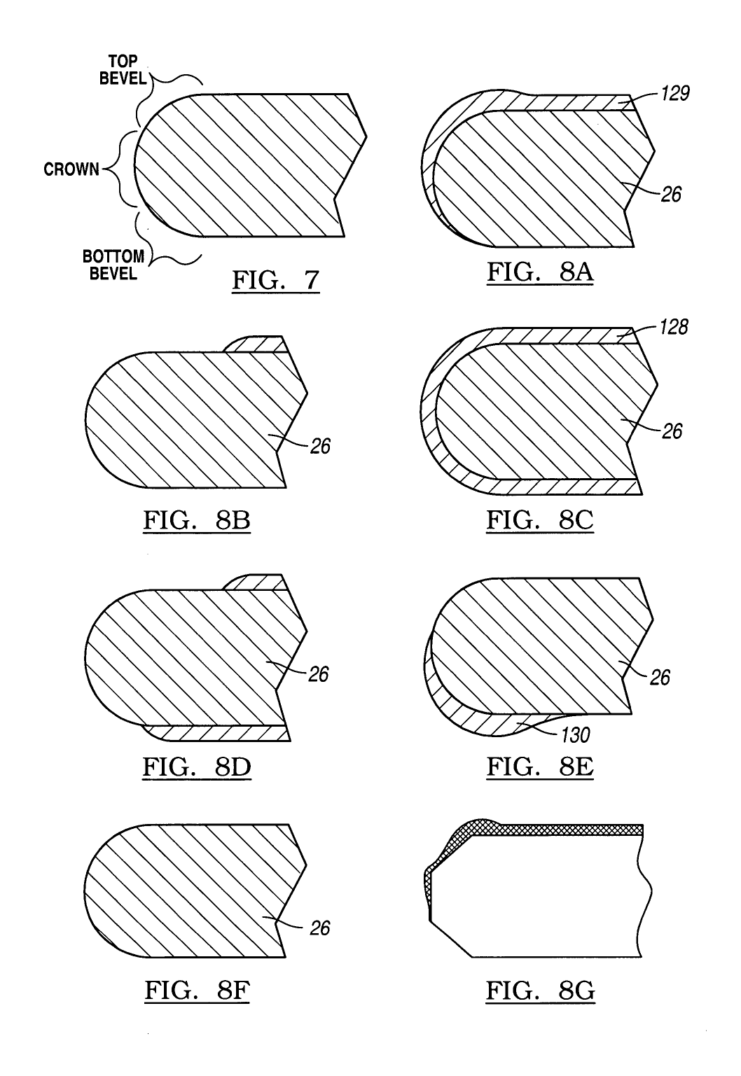

Referring to FIGS. 7 through 8G, a film such as deposited through chemical vapor deposition (CVD) or physical vapor deposition (PVD) extends as a thin film 129 over a wafer 26 such as a wafer. The thin film 129 extends from the top surface of the wafer 26 across a top bevel, crown and bottom bevel of the wafer 26. The above-described system 20 can be advantageously used to process the thin film 129 on the wafer 26 resulting in a wafer 26 profile as shown in FIG. 8B.

Referring to FIGS. 7 and 8C, a full coverage thin film 128 extends from the top surface across the top bevel, crown and bottom bevel and onto the bottom surface of the wafer 26. Thin films having this profile can include for example thermal SiO₂, and Si₃N₄. Embodiments of the above-described system 20 can be used to process the full coverage thin film 128 on the wafer 26 resulting in a wafer 26 profile as shown in FIG. 8D.

Referring to FIGS. 7 and 8E, a backside polymer thin film 130 extends from at or near the top bevel to across at least a portion of the crown to the bottom bevel and onto the bottom surface of the wafer 26. Embodiments of the above-described system 20 can be used to process the backside polymer thin film 130 on the wafer 26 resulting in a wafer 26 profile as shown in FIG. 8F.

Now referring to FIGS. 9A-9C, an alternative embodiment edge area processing system 20′ (the “first alternative system”) employ alternate first and second nozzles 45, 49. In the alternate nozzle configurations, the second nozzle “bends” the reaction gasses from the first gas around the bevel edge.

FIG. 9A represents a 65°/140° nozzle configuration. This configuration allows the gases of the reaction to be induced around the wafer 26 bevel. Each of the four nozzles 45,49 is constructed of sapphire with a bore diameter of 0.254 mm and an aspect ratio of between 10:1 and 80:1 at the outlet end. Each of the four nozzles 45,49 is press fitted into the nozzle assembly 84. The nozzles are pressed into tightly toleranced bores cut into the stainless steel nozzle assembly 84. Nozzle diameter is 1.577 mm, +0.003 mm, −0.000 mm. Bore diameter in the nozzle assembly 84 for receiving the sapphire nozzle is 1.567 mm, +0.003 mm, −0.000 mm. This gives an interference fit in the range of 0.007 mm to 0.013 mm. Tolerance of this fit is important as interference in this range allows a hermetic seal while only inducing elastic deformation in the stainless steel nozzle assembly 84. This allows a good seal without causing particulate generation during processing. In this configuration, a spoiler jet 89 is used to ensure the flame does not interact with the structure system 56. Additionally, the lower moat 51 ensures reactants do not pass the isolator so as to affect the back surface.

FIG. 9A shows that under some processing conditions, flame outputs may impinge on portions of the exhaust or isolator structures. Although moat 51 gasses generally can be used to prevent reaction gasses from flowing upstream, under certain processing conditions, the gasses may be forced toward the chuck 28. As seen in FIG. 9B, the use of a spoiler jet 89 can reduce or eliminate the reaction gas impingement. Additionally, the gas flow through the backside moat will eliminate the chance reaction products will migrate into the wafer back surface.

Although NF₃ is used in the above embodiments as the non-oxygen oxidizer other non-oxygen oxidizers as previously discussed are suitable for use in the preferred embodiments. Further, additional embodiments for isolating and processing a wafer according to the above-described method are disclosed in U.S. patent application Ser. No. 11/230,263, filed on Sep. 19, 2005 and titled “Method and Apparatus for Isolative Substrate Edge Area Processing.” The disclosure of this application is incorporated herein by reference.

Removal of dielectric thin films such as silicon oxide from substrates using H₂ and NF₃ gas mixtures is performed with a hydrogen fraction in the range of 0.5 to 0.7. For example, if the total flow is 800 sccm, H₂ flow will be in the range of 400 sccm to 560 sccm with NF₃ flow in the range of 400 sccm to 240 sccm. IR preheat is used in cases where ambient oxygen is present to discourage combustion products from condensing on the substrate.

Removal of tantalum from the near-edge region of the substrate is carried out using an etch nozzle configuration similar to that detailed for dielectric removal. Total gas flow per nozzle is approximately 400 sccm with an H₂ fraction in the range of 0.6 to 0.7. The primary tantalum etch product is TaF₅ which has a boiling point of ˜230° C. Substrate surface temperatures in the etch region must be kept about this temperature to prevent condensation of the etch product. This is readily achieved using an additional combustion flame nozzle (not shown) positioned to impinge a flame on the substrate immediately prior to the impingement of the etch flame. This pre-heat nozzle discharges a flame of H₂ and O₂ preferably in the range of 0.5 to 0.8, H₂ fraction at a total flow of ˜400 sccm for a single nozzle.

A rate of etching of the edge portion of the wafer 26 can be calculated based on consideration of exposure width, wafer circumference and rotational speed. For example, consider a 200 mm circumferential wafer with 2,000 Å of SiO₂ that is rotated at 2 rpm and the SiO₂ thin film on the edge area is completely removed in one rotation. Assuming a conservative exposure width of 5 mm of the combustion flame effluent on the wafer edge (using a 0.256 mm nozzle bore) an exposure fraction can be calculated as 5 mm/(628 mm×2 rev/min)=0.004 min/rev. The etch rate can then be approximated by dividing the 2,000 Å/rev removal by the exposure fraction. That is 2,000 Å/rev/0.004 min/rev=500,000 Å/min SiO₂ removal. If a smaller 2 mm exposure width is assumed then the removal rate becomes 1,256,000 Å/min. Based on these considerations and assumptions a poly-silicon thin film would be etched at an approximate rate of 3×10⁶ Å/min; a photoresist thin film would be etched at an approximate rate of 4.6×10⁶ Å/min; and a tantalum thin film would be etched at an approximate rate of 1×10⁶ Å/min. This is a significantly high rate of etching resulting in a high rate of processing throughput of wafers.

One configuration is optimized for EBR from spin-on films on the top surface and edge region of wafers. This configuration uses reactive gas generated by a combustion flame of H₂ and O₂ to remove the resist. The present disclosure defines an optimized process using a minor fraction of the non-oxygen oxidizer NF₃ in the gas mixture for photoresist EBR. This addition increases the combustion flame temperature and chemical reactivity. These modifications to the combustion flame mixture substantially enhance sharpness of the etch interface and increase slope of the transition to full film thickness, both highly desirable enhancements.

For spin on films with low or minimal etch rate in the H₂:O₂ dominant chemistry such as organosilicates, inorganic polymers, and spin on glass materials, increasing amounts of fluorine containing gases such as NF₃ can be added to further increase etch rate. In this embodiment reactive gas application to the near edge area of the wafer is achieved using the invention disclosed in “Method and Apparatus for Isolative Substrate Edge Area Processing,” previously incorporated by reference.

Undesirable dielectric films can be removed from the front surface of in process semiconductor wafers. These films can also flake and result in defects which cause yield loss. Concentric process application is critical in these processes where reactive gas application must be targeted to the edge region while not affecting the device area of the wafer.

Tantalum removal is similar in configuration to the front side dielectric removal module. Differences exist in the use of a preheat nozzle to reach a higher surface temperature (>230° C. target) to prevent TaF₅ condensation in the etch region. Surface temperature pre-heat target for typical film removal is ˜120° C. and is primarily to prevent condensation of water vapor byproduct from the combustion reaction.

The in-situ wafer centering sequence typically takes 8 to 15 seconds. This overhead can be overlapped with gas flow stabilization time or ignition sequence. Wafer ‘z’ plane displacement is measured during rotation and can be used to map out ‘z’ displacement due to wafer bow or warp.

Process operation and details for Ta and dielectrics is discussed at length in the “Substrate Processing Method and Apparatus Using a Combustion Flame” patent application, previously incorporated by reference. This process operation can be applied to backside polymer and edge bead removal.

Backside polymer removal according to the principles of the present disclosure is accomplished by using four nozzles located in the isolator structure. As shown in FIG. 9C, two nozzles are positioned at 45 degrees and two are at 105° relative to the wafer surface. The 45° nozzles are aimed at the back surface while the 105° nozzles are aimed at the bevel. In some cases, 2×45 degree nozzles are directed at the back surface along with 2×65 degree nozzles directed at the bottom bevel. Using multiple nozzles in this fashion both increases throughput and widens the process window. Nozzle angle relative to the wafer surface is important as impingement angle affects flow attachment to the surface and consequently degree of delivery of reactive species to the surface. As previously mentioned, an optional spoiler jet 89 can ensure the 105° nozzle does not cause degradation of the exhaust structure. It should also be noted that in this configuration, gas from the moat 51 can be used to “spoil” the flow of the flame to ensure it does not interfere with the exhaust.

Typically, the thickest polymer is located on the bevel region of the wafer. Consequently the NF₃ fraction in the 105° jets is higher than the 45° jets aimed at the thinner polymer on the back surface. Currently the method process uses 210 sccm H₂, 80 sccm O₂, and 100 sccm NF₃ in each 105° (high fraction) nozzle. Flows of 240 sccm H₂, 120 sccm O₂, and 20 sccm NF₃ are used in each 45° (low fraction) nozzle. The nozzles are constructed from sapphire with an ID of approximately 254 μm and an aspect ratio of greater than or equal to 10:1. Rotational speeds using during process are typically in the 1 to 6 RPM range. Surface heating for condensation prevention (>100° C. target) is done using a fiber coupled laser diode array.

Chemistry used for EBR depends on the film being removed. For photoresist removal 240 sccm H₂, 120 sccm O₂, and 20 sccm NF₃ performs well. Rotation rate to remove 15,000 Angstroms of resist is typically 1 to 3 RPM. Two nozzles are used for the photoresist EBR process, one at 45° and one at 65°. In cases where minimum edge exclusion is desired (˜0.5 mm) only the 65° jet is used. Films with low removal rate, typically silicon containing films, require higher NF₃ fraction. The high fraction process used for backside polymer is an example (25% NF₃) although higher fractions can be used, frequently without oxygen addition, to ˜50%.

Nozzle aiming for backside polymer removal is shown in FIG. 9C. Backside polymer removal approach differs from front side films in that a sharp transition to full film thickness at the edge exclusion boundary is not required. Multiple nozzles are used in a partially overlapping fashion to increase the process window and removal rate. Nozzles are angled at 45° and 65° relative to the wafer surface. These angles were determined by a combination of CFD modeling and experimental trials. Positioning of the 65° nozzles can be critical for flow attachment and consequently efficient removal of material from the bevel region. This angle can be optimized based on edge profile to maximize flow attachment.

FIG. 10 shows a schematic view of the centering process. The measurement window of the laser micrometer 15 is represented by a rectangle 20°. The edge location of a properly centered wafer or circle of radius 150 mm is shown as 202. The target center position of the wafer is (X_{c}, Y_{c}). A misaligned wafer is shown in hidden line representation at two different angular positions. At a first position identified as 204, the pre-centered wafer has been rotated about the Z axis θ1 degrees. The center of the wafer is identified at (X₁, Y₁). A second wafer position, identified as 206, corresponds to the wafer being rotated an angle of θ2 degrees. The center of the wafer is now at (X₂, Y₂).

FIGS. 3 and 10 depict a “Z” axis, an “R” axis and θ angles from a reference coordinate system having an origin at (X_{c}, Y_{c}). The edge position measurement and offset calculation includes the following: 1. R-Z-θ stage placed with θ axis in known reference location; 2. Rotate θ and measure radial position of wafer edge using laser micrometer 15; 3. Measured radii are fit to a circle; and 4. The difference in position between the known θ axis and the center of the resultant fit circle is calculated and gives magnitude and angle of wafer offset.

The centering routine measures and records θ, T₁, (1 . . . n) and the laser micrometer 15 reading, Lᵢ, (1 . . . n) which represents the edge position. Typically n=50 in this application. The true radius of the wafer is assumed (100 mm or 150 mm). Theta is referenced using the wafer notch position. The following values are computed for each data point:
Xᵢ=(R+Lᵢ)·cos(Tᵢ) 1a
Yᵢ=(R+Lᵢ)·sin(Tᵢ). 1b

The objective is to minimize the sum of squares of the deviations given by
Dᵢ=(Xᵢ−X_{c})²+(Yᵢ−Y_{c})²−R_{c}² 2
where X_{c} is the x-axis center point, Y_{c} is the y-axis center point and R_{c} is the assumed radius. The Gauss-Newton method is used to solve the set of non-linear equations. An example of this method is given in “Least-Squares Fitting of Circles and Ellipses” by Gander, et. al. published in BIT, vol. 34, 1994, pp. 558-578.

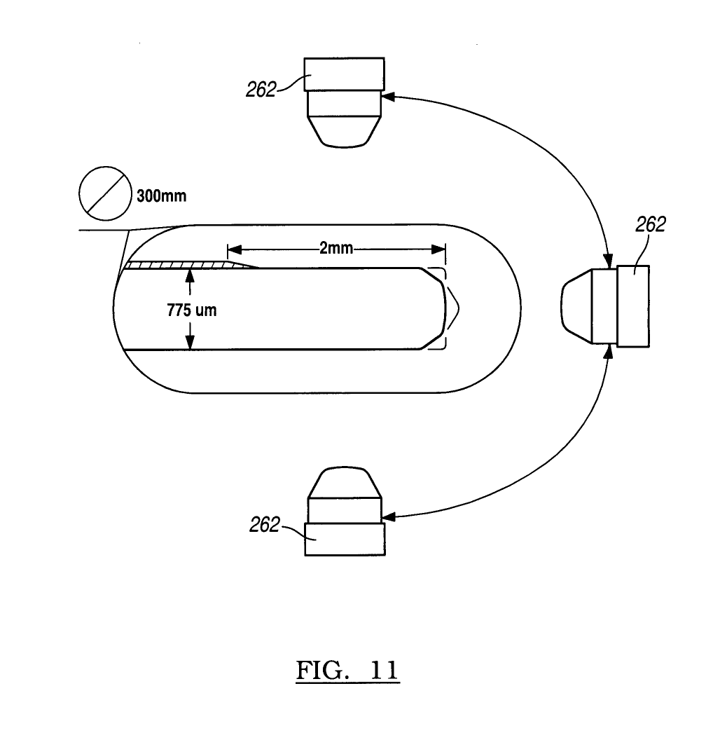

As best in FIG. 11, the system 20 can include an optical system 264 inspecting the wafer's edge. In this regard, the optical system has at least one zoom lens 262 which is rotatably positionable about the wafer's edge. The zoom lens is configured to be able to take reflected light from the wafer's edge and collect it into a CCD camera. It is envisioned that the zoom lens will have a 2 μm resolution and will be able to detect defects on the wafer's edge as well as the effectiveness of the cleaning process.

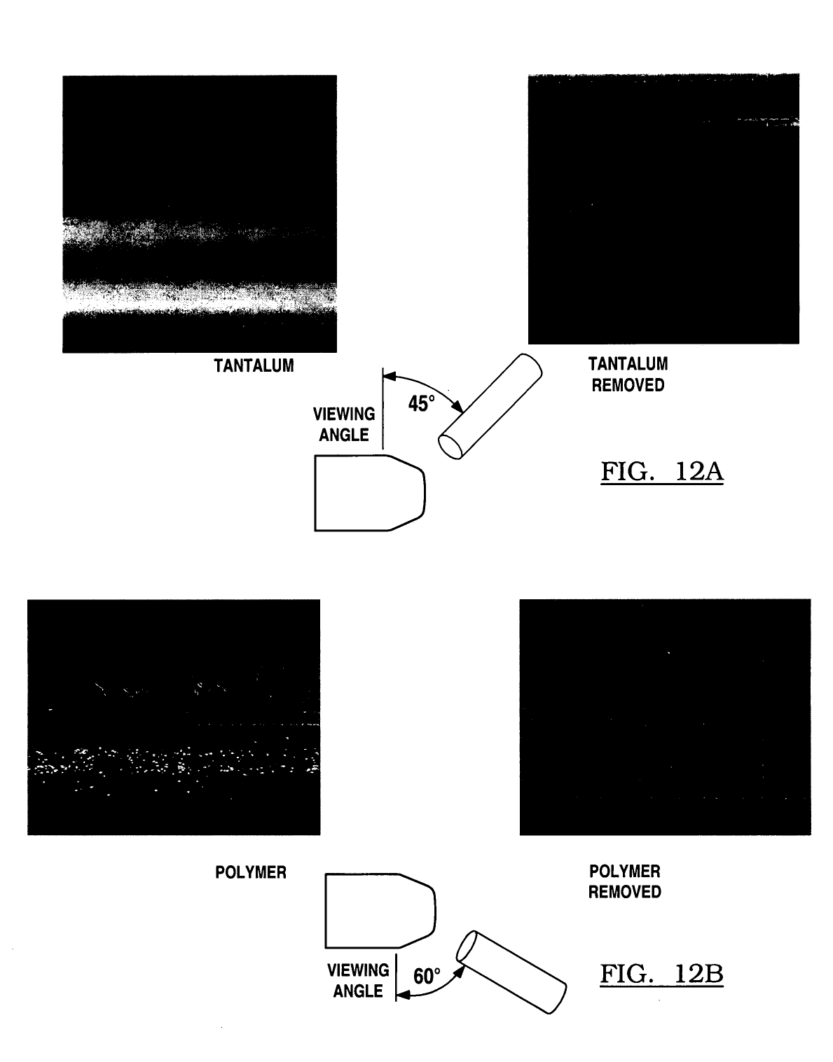

As shown in FIG. 12A, the system 20 described above remove TA on the bottom level of the edge. Further, as shown in FIG. 12B, the system is capable of removing polymer from the top of the wafer, revealing a dielectric surface. Additionally, it is envisioned the system can use thin film spectroscopic reflectivity. Further, the optical system is disclosed in U.S. patent application Ser. No. 11/417,297, filed on May 2, 2006 and titled “Substrate Illumination and Inspection System,” previously incorporated by reference above.

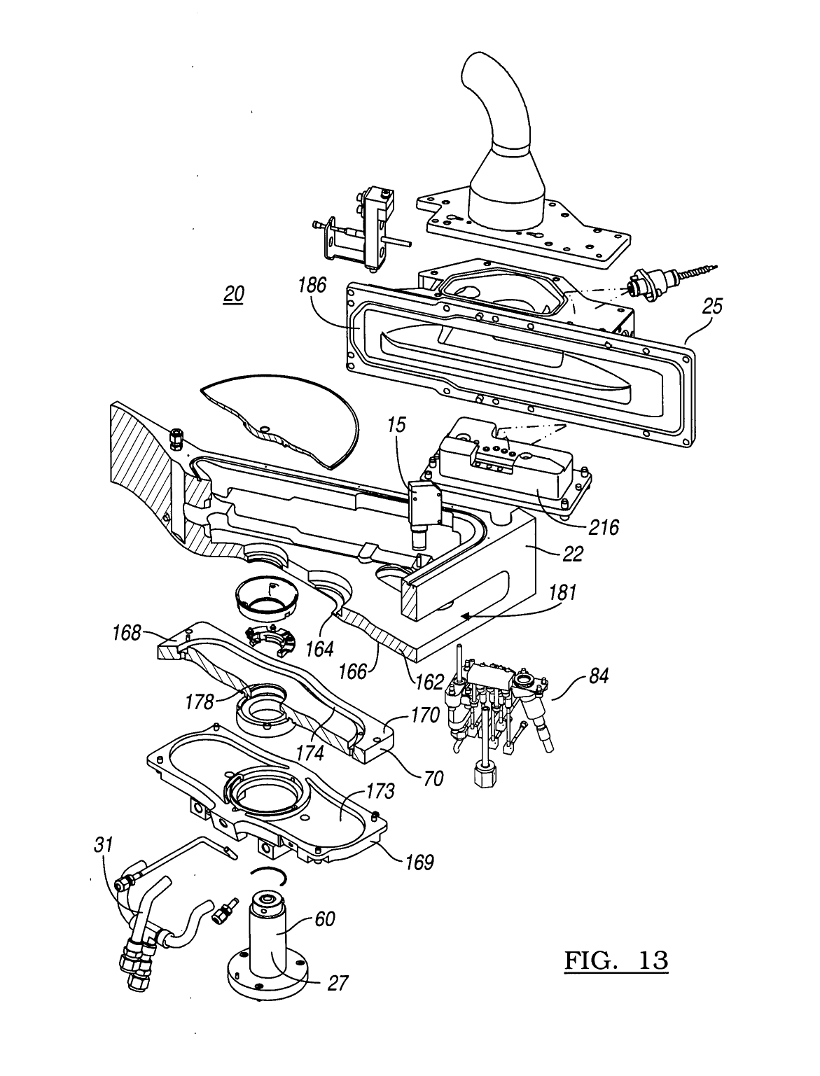

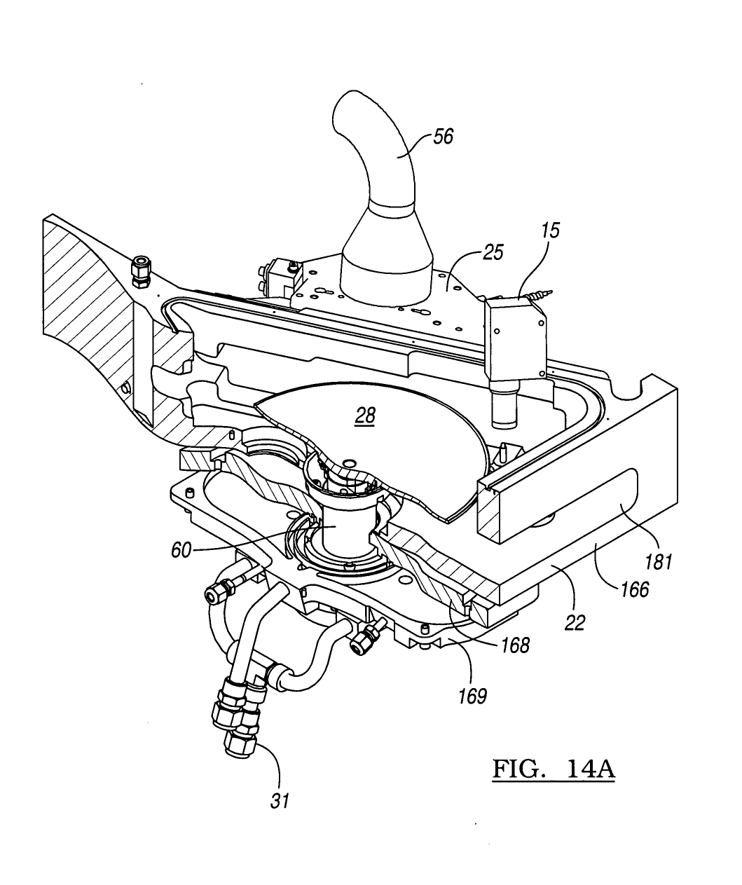

As can be seen in FIGS. 13 through 16B, the wafer processing system 20 includes the wafer movement system 27 having a spindle 60 configured to move the wafer in three or four axes of movement. In this regard, the wafer movement system 27 is configured to move the wafer within an isolated chamber 22 in rz-θ or xyz and θ directions (motion occurs in r,z and theta directions). The isolated chamber 22 has a bottom wall 162 defining an aperture 164 and having a first exterior bearing surface 166. The labyrinth seal 70 has a sealing plate 168 having a second bearing surface 170 is slidably positioned against the first bearing surface 166. The sealing plate 168 further defines a bore 172 which is annularly disposed about the spindle 60. A first vacuum chamber 174 is defined between the first and second bearing surfaces 160, 170. Additionally, a vacuum source is coupled to the first vacuum chamber 174.

FIG. 13 represents and exploded view of a portion of the wafer processing assembly 20. Shown is a portion of the chamber 22, the labyrinth seal 70 and associated isolator assembly 25 components. As can be seen, the labyrinth assembly 70 is formed of a sealing plate 168 and support plate 169. The support plate 169 defines a vacuum gallery 173 which is fluidly coupled to the vacuum chamber 174 defined between the first and second bearing surfaces 160 and 170 of the chamber bottom wall 162 and sealing plate 168 bearing surface 170. Also shown is the relationship of the spindle 60 and the apertures 172 and 164 formed in the sealing plate 168 and the bottom wall 162. Also shown is the relationship of a loading position 181 and the second processing position 186.

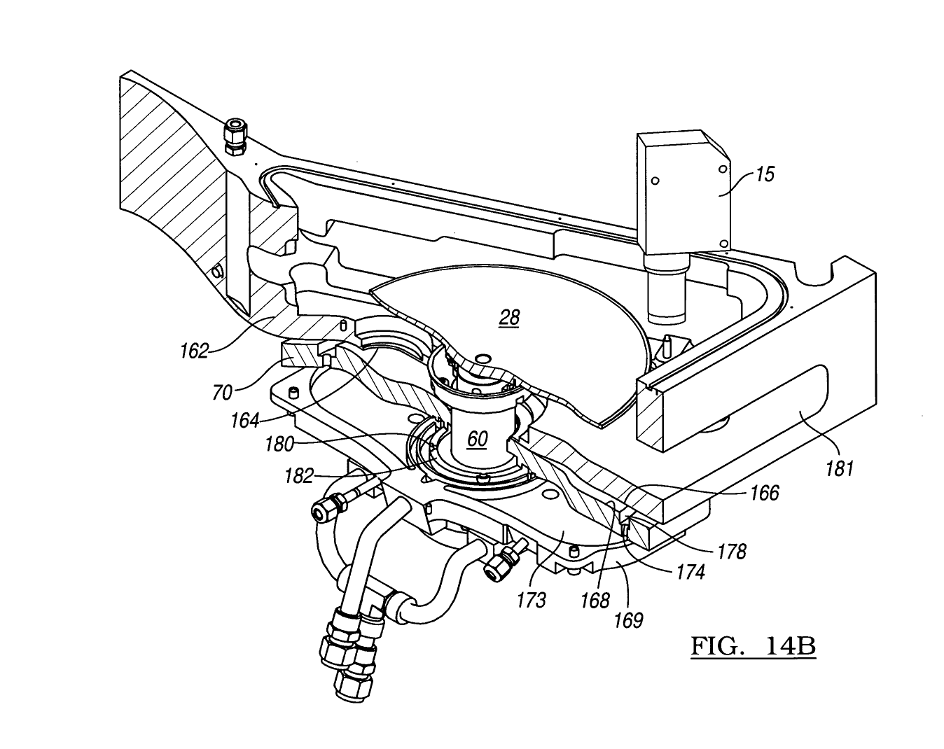

As best seen in FIGS. 14A-B and 15, either the first or second bearing surfaces 166, 170 can define a groove 178. This groove 178 forms a portion of the first vacuum chamber 174 defined between the first and second bearing surfaces 166 and 170. This chamber 174 is movable with respect to the bottom wall 162 upon movement of the spindle 60 by the actuation mechanism.

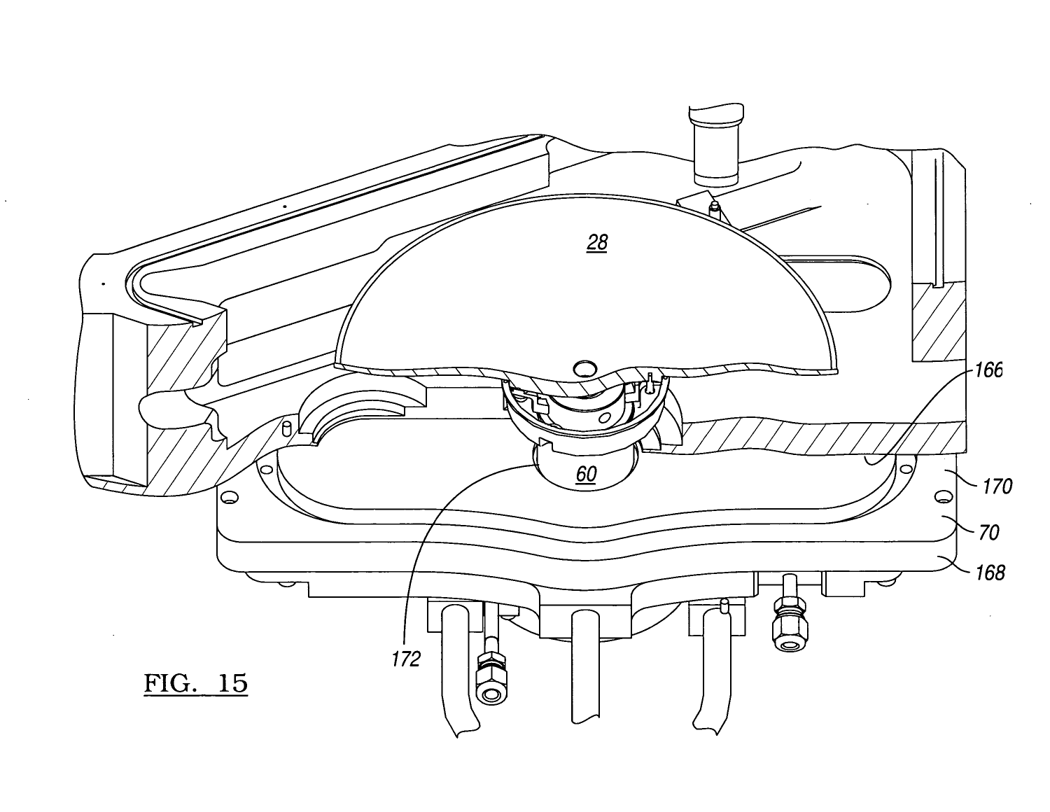

Adjacent to the bore 172, the sealing plate 168 can define second groove 180. A second vacuum chamber 182 can be defined between the second groove 180 and the spindle 60. This second vacuum chamber 182 can be independently coupled to the vacuum source 176. As best seen in FIG. 15, the wafer movement system 27 comprises a wafer supporting chuck 28 that functions to fixably hold the wafer 26 through the movement system 27. This wafer movement system 27 is configured to move the wafer 26 from the loading position 181 to a second processing position 186. In this regard, the processing position can be an alignment position or can be positioned adjacent to the nozzle assembly 84.

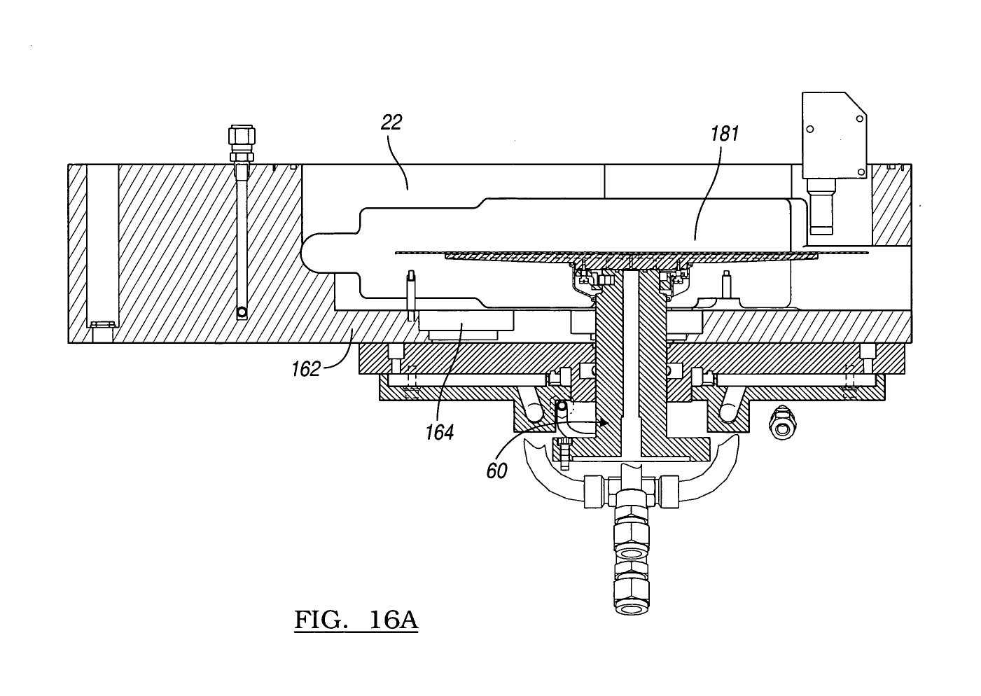

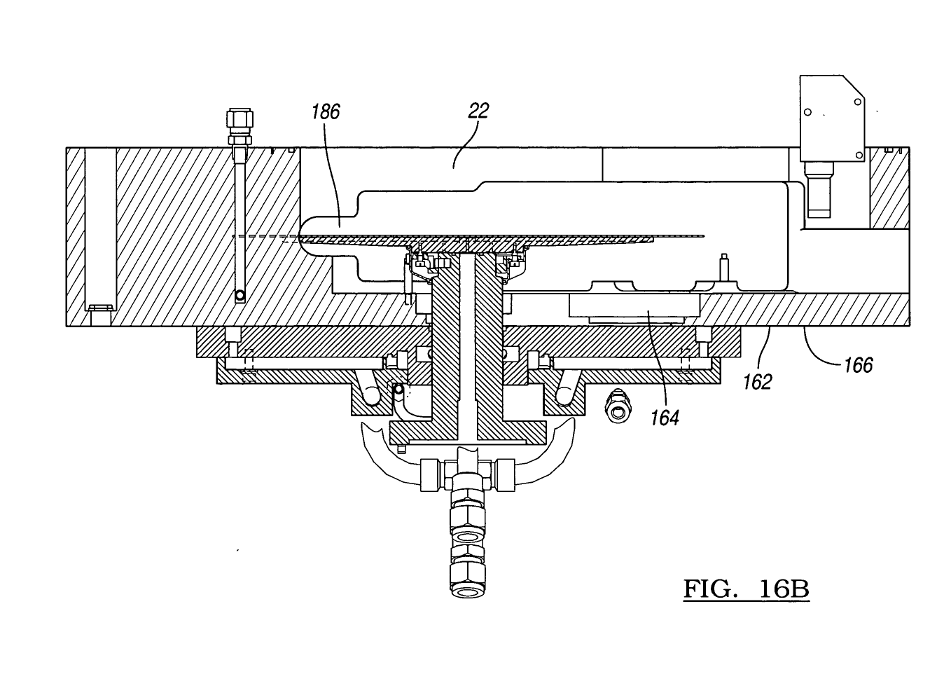

With reference to FIGS. 16A and 16B, the operation of the wafer movement system 27 is disclosed. The spindle 60 is configured to move the wafer 26 in a plurality of directions from the loading position 181 to the processing location 186. The isolated chamber 22 is disposed about at least a portion of the wafer movement system 27 in order to protect the mechanism of the wafer movement system 27 from the reactive gases generated during the processing of the wafers. The chamber 22 has bottom wall 162 defining an elongated bore 164 which allows the movement of the spindle 60 with respect to the chamber 22. The bottom wall 162 first bearing surface 166 can either be located on an exterior or an interior surface of the chamber 22.

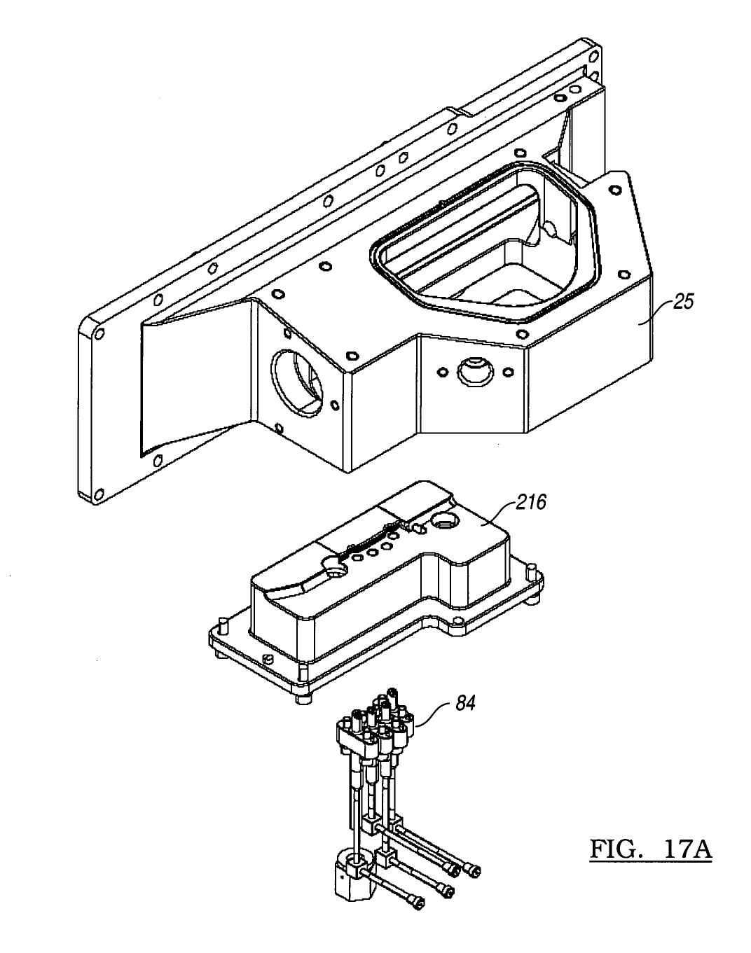

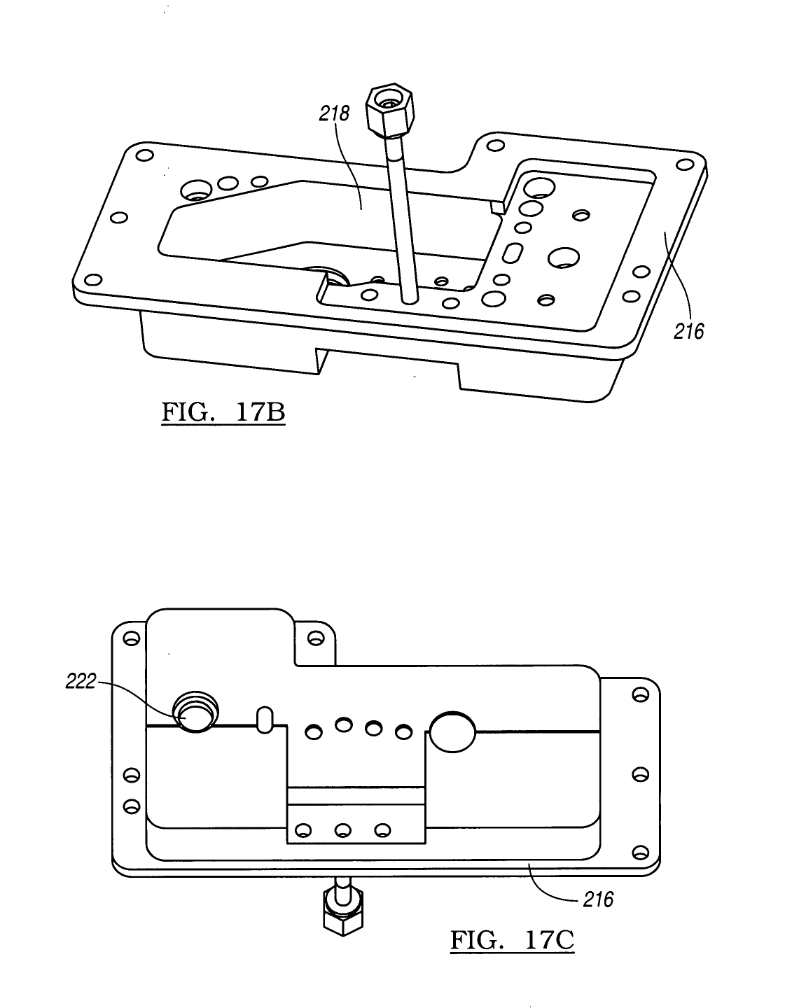

FIGS. 17A-17B represent an exploded sectional view of isolator 25. The isolator 25 has a nozzle plate 216 which provides the mechanism to couple the nozzle assembly 84 and moat 51 gas supply to the moat 51. The nozzle plate 216 defines a recess 218 which slidably accepts the nozzle of the nozzle assembly 84. The recess 218 further defines a second recess aperture 220 which accepts an optical interface for the heating element 122. The nozzle plate 216 allows for the configurations of the nozzle assembly 84 without the entire disassembly of the wafer processing apparatus 20. As shown in FIGS. 17B and 17C, the nozzle plate 216 defines apertures and fixation pins which facilitate the alignment of the various components to the isolator 25. In this regard, the nozzle assembly 84, heater 122 and moat 51 gas supply lines are precisely positioned.

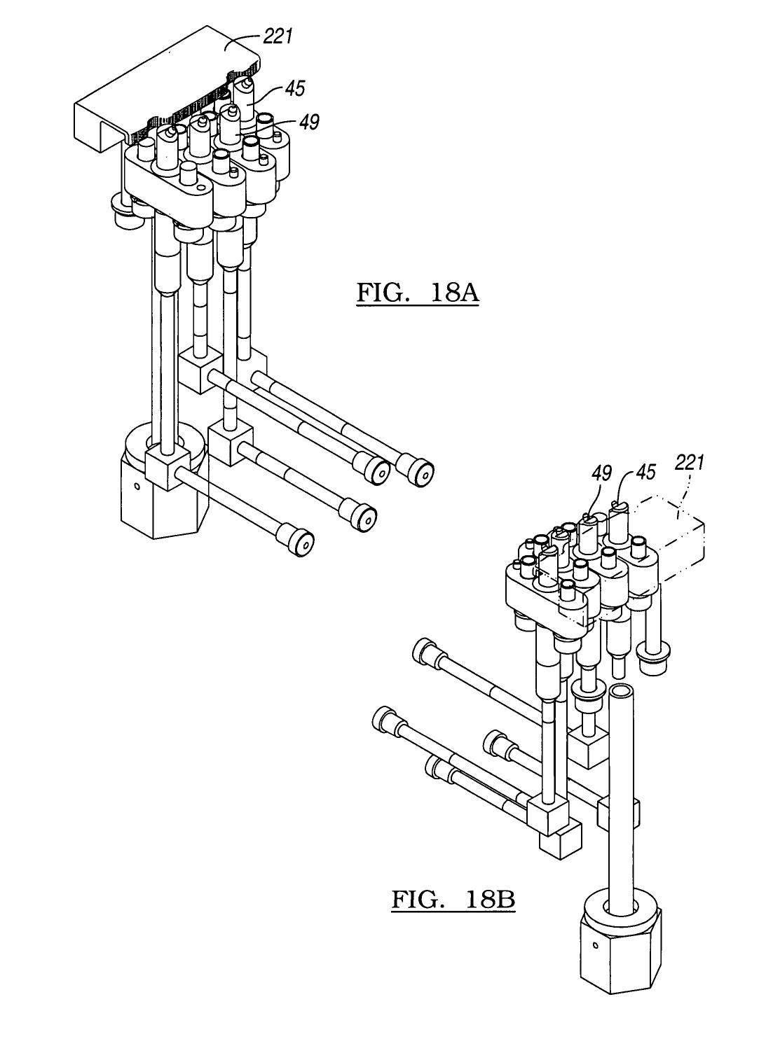

FIGS. 18A and 18B show a plurality of nozzles 45,49 coupled to a diffusion portion 221. The structure 221 forms a plenum when installed against the nozzle plate 216. The support member 221 fits within the recess 218 of the nozzle plate 216 to position the nozzles 45 in their proper orientation.

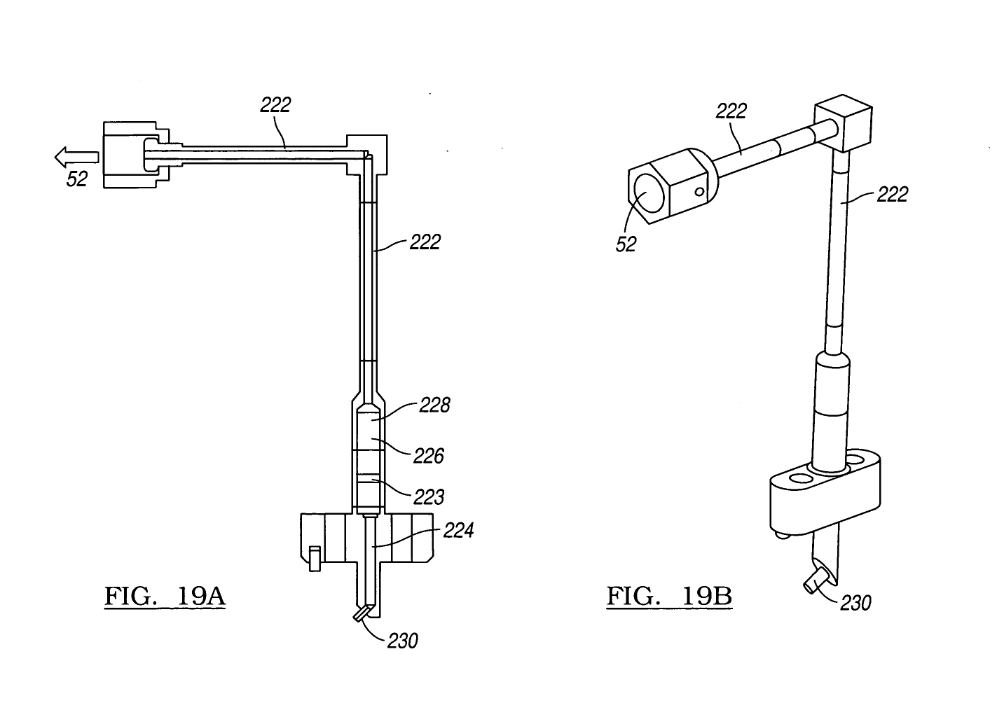

As shown in FIGS. 19A and 19B, the nozzles are coupled to the gas supply 55 through a plurality of welded stainless steel tubes 222. To maintain flame stability, the gas supply 55 is controlled by controller 52. As previously disclosed, the nozzles have a stainless steel lead-in tube 224 having a very high aspect ratio. For example, for H₂ and O₂ gas mixture, an aspect ratio of greater than or equal to 10:1 is appropriate.

Disposed immediately before the lead-in portion 224 of the nozzle 45 is a blowback flash suppressor device 226. This device 226 is a chamber 228 having a volume significantly larger than the volume of the lead-in portion 224. Disposed within the volume is a porous stainless steel member 228 which functions as an energy sink to prevent the flame front from traveling up through the nozzle 45,49 and into the gas supply in the event of a system failure.

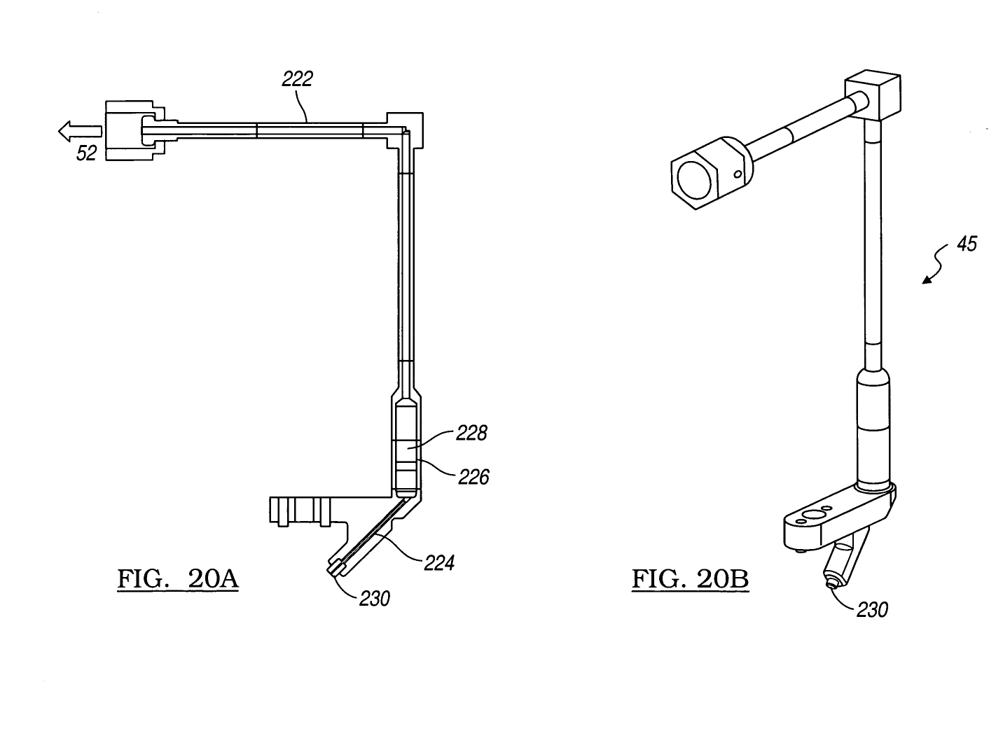

As shown in FIGS. 20A and 20B, the aspect ratio of the nozzles 45 can vary depending on the fuel and oxidizer being used. In this regard, in situations where a high percentage of NF₃ is being used as an oxidizer, the nozzle 45,49 has a stainless steel lead-in portion 224 having an aspect ratio of greater than 40:1, and preferably 80:1. As with the other nozzles, high purity nozzle tips 230 of sapphire are preferred. The nozzle 45 has a stainless steel body 225 with locator pin 227 which allows for the coupling of the nozzle 45 with nozzle support member 221.

Disposed within the mass flow controller 52 is a normally open valve (not shown) which functions to dump CDA into the fuel supply source should the power be interrupted. Additionally, should the system 20 desire to shut off the processing nozzles 45,49 the normally opened valve is actuated and allows CDA at a pressure higher than the pressure of the fuel source to flow into the processing nozzles 45, effectively extinguishing the flames without the risk of a system explosion.

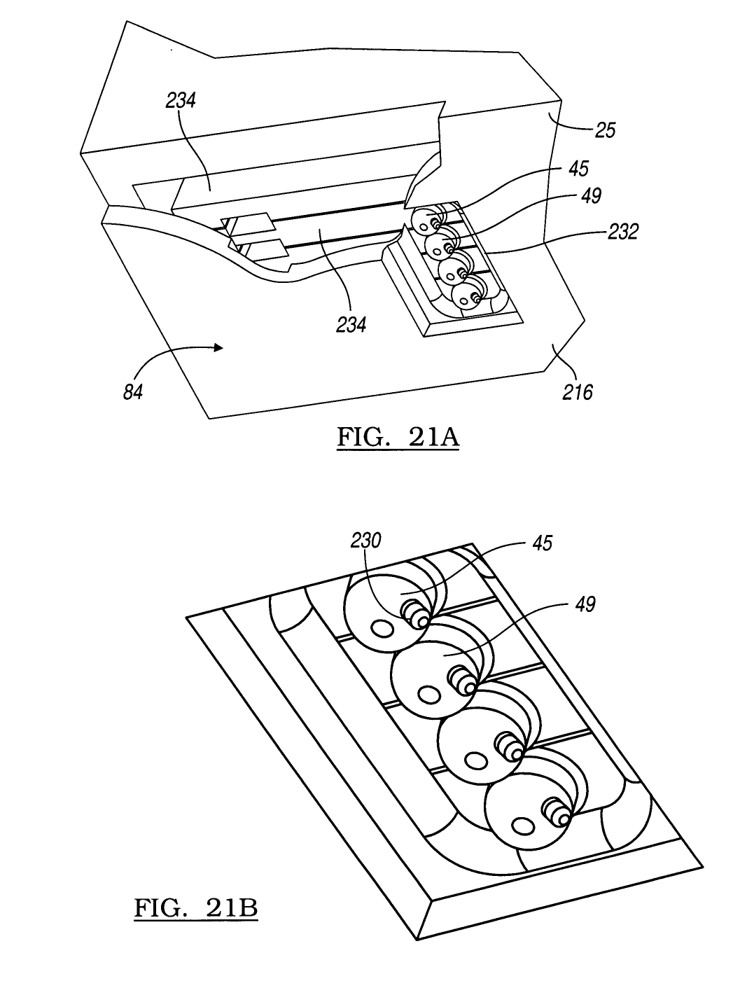

FIGS. 21A and 21B represent an alternate method of coupling nozzles to the isolator 25. Shown is an aperture 232 defined into either the isolator 25 or the nozzle plate 216. Disposed within the aperture 232 are a plurality of nozzle subplates 234 which have individual nozzles 45. These nozzles subplates 234 are movable with respect to each other in fore and aft directions to allow for relative positioning of the subplates within the isolator 25. The individual nozzle subplates 234 can be stacked immediately adjacent to each other to form a nozzle assembly 84.

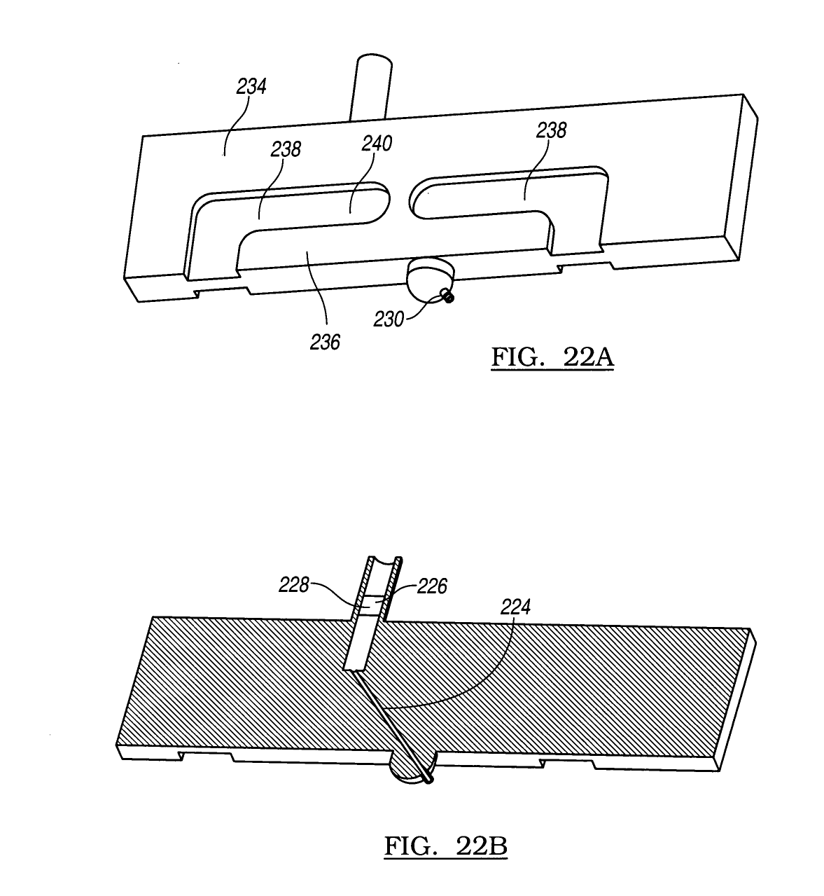

FIGS. 22A and 22B depict individual nozzle subplates 234. Disposed on the inner face surfaces 236 of the nozzle subplates 234 are grooves 238 which function as fluid chambers 240. These fluid chambers 240 are coupled to a vacuum or pressurized gas source (not shown) and function to divert reaction gas products which might leak from the processing chamber 22 during wafer processing. It is envisioned that inert or oxygen containing gas can be supplied to the nozzle plate, which will in turn flow into the isolator through the aperture 232.

FIG. 22B depicts a cross-sectional view of the nozzle plate 234 shown in FIG. 22A. As can be seen, structures such as the high aspect ratio lead-in tube 224 and blowback flash suppressor device 226 can be machined therein. These features significantly reduce the cost of the assembly and increases the overall system reliability.

In operation, fuel is provided to the nozzles 45, through the flash suppressor device 226 from the mass flow controller 52. The vacuum source draws a vacuum in the vacuum chamber 236 preventing corrosive reaction gases from leaking past the nozzle assembly 84.

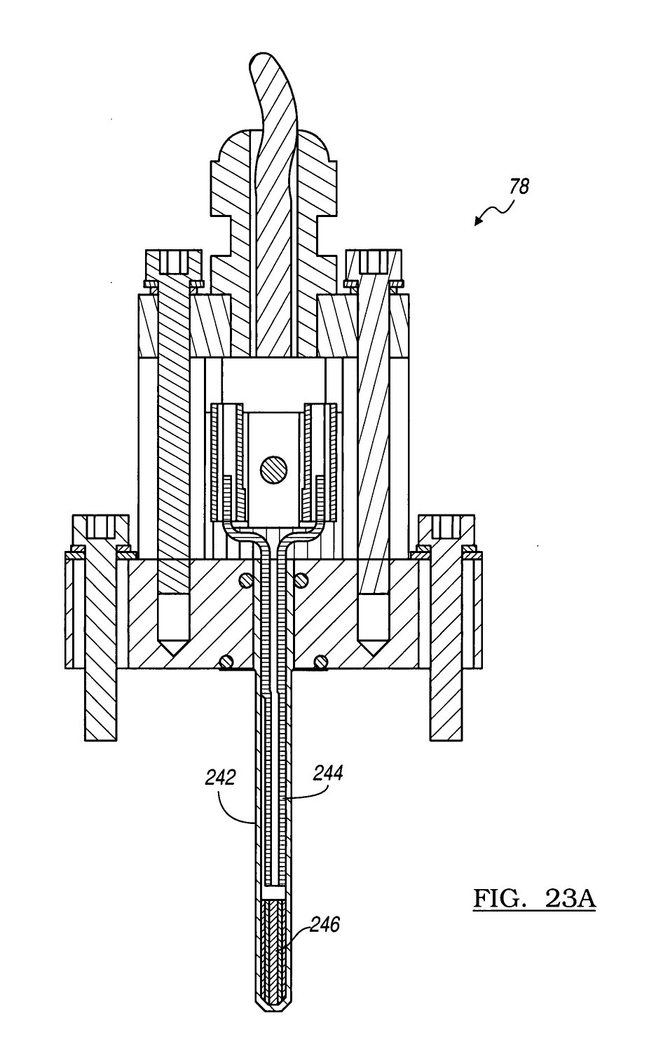

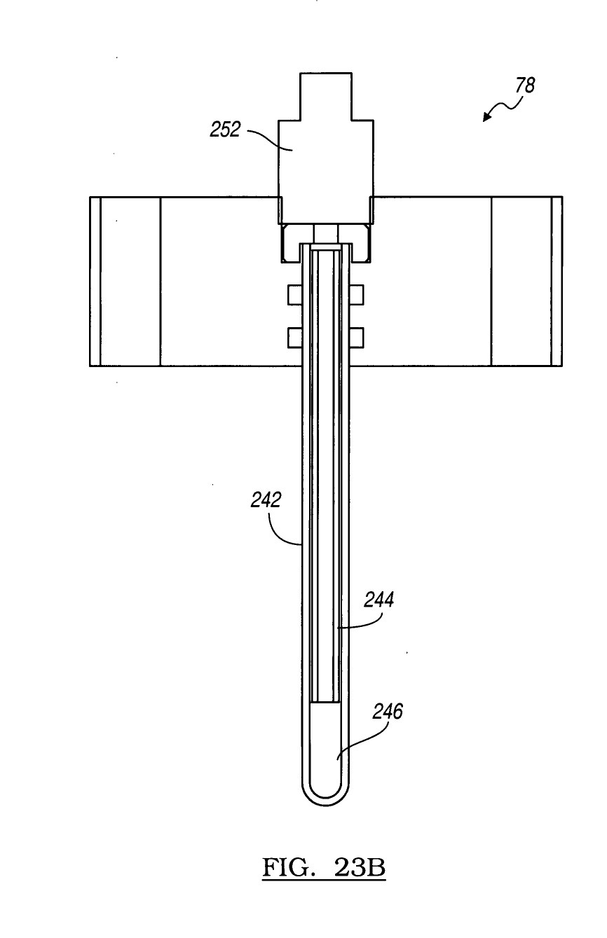

FIGS. 23A and 23B, represent an igniter assembly 78 which is configured to cleanly ignite the nozzles 45 and 49 of the nozzle assembly 84. The igniter assembly 78 has an optically clear or sapphire hot body igniter 242 defining an interior cavity 244. The hot body igniter 242 provides high chemical resistance, which is non-particle forming. A heating element 246 is disposed within the interior cavity 244. This heating element, which can be a Pt:Rh element, functions to quickly bring the hot body igniter to a predetermined temperature which will ignite a fuel oxidizer mixture when the fuel touches the igniter hot body 242.

As seen in FIG. 23B, the ceramic hot body igniter 242 can be physically and optically coupled to a laser diode 252. In this configuration, the laser diode 252 is configured to produce photons which past through the interior cavity 244. These photons strike the heating element 246, thus producing a reliable ignition system. Alternatively, the hot body 242 can be coated on an interior or exterior surface with materials which increase photon absorbance at wavelengths of interest.

Disposed at a distal end of the elongated cavity 244 is the heating element 246. This heating element 246 can be electrically coupled to a power source which functions to provide electric current to heat the heating element. Alternatively, this element can be inductively heated.

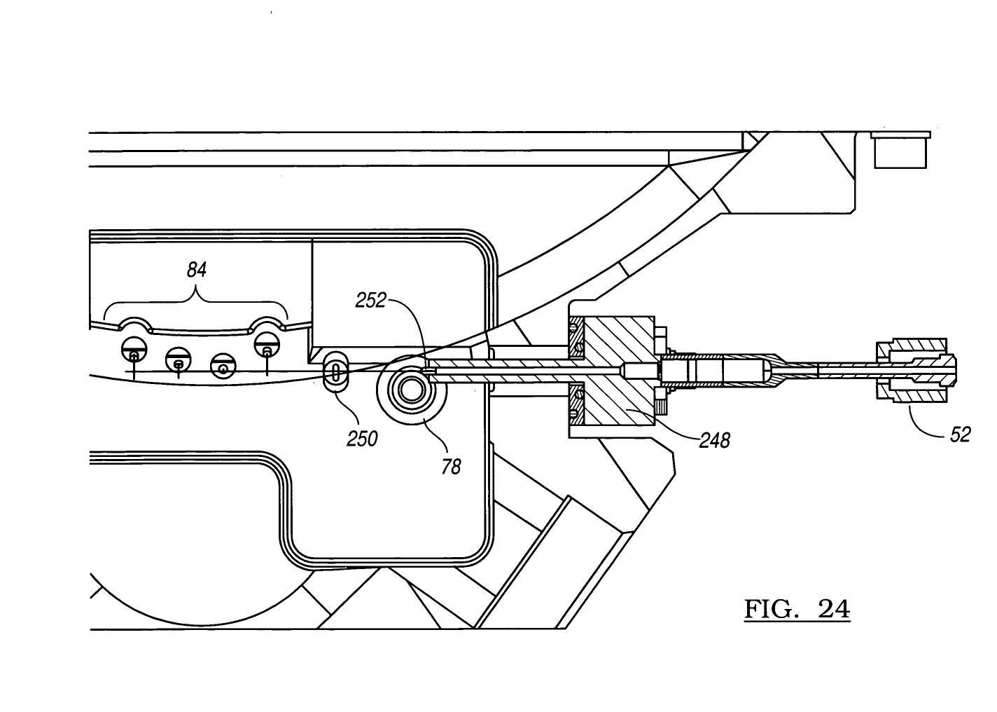

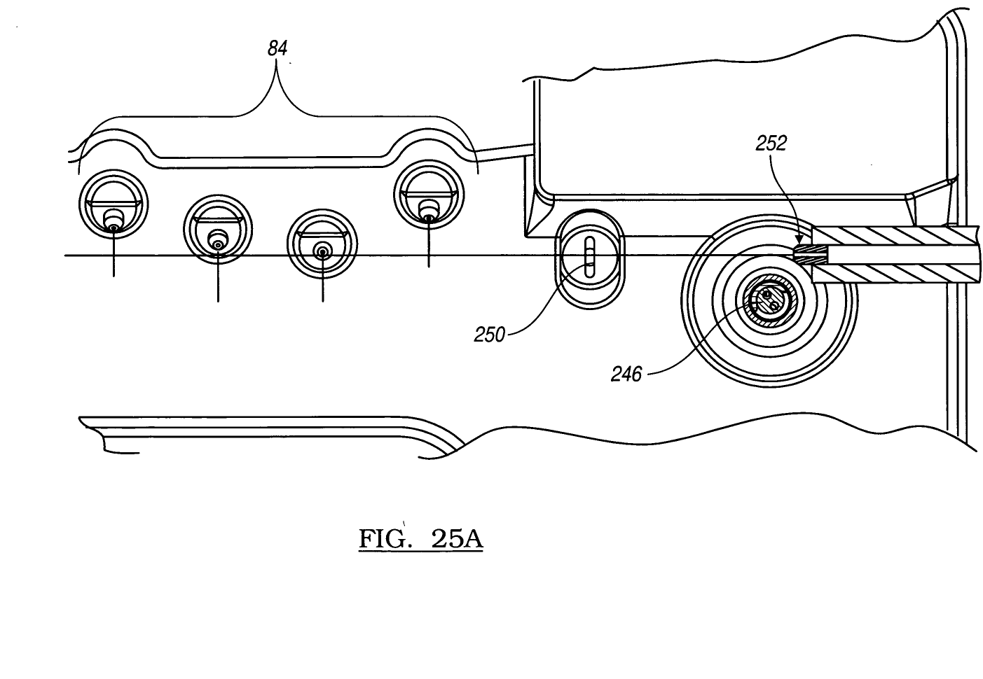

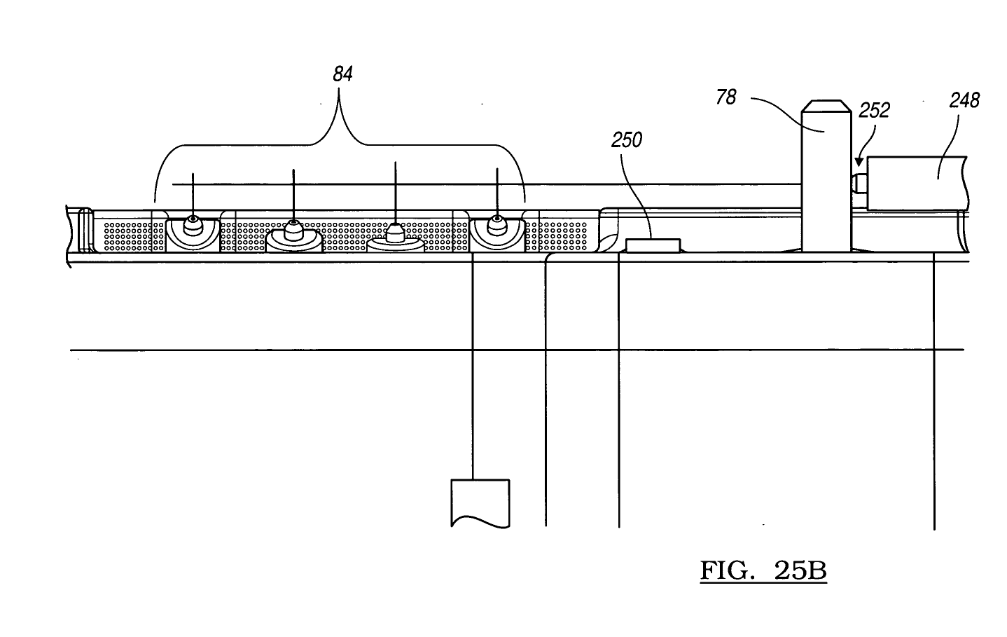

As shown in FIGS. 24 and 25B, operably disposed between an igniter nozzle assembly 248 and the nozzle assembly 84 is an air knife 250. The Air knife 250 is fluidly coupled to a source of CDA or inert gas. The igniter nozzle assembly 248 is operably coupled to a fuel source 52 and can have a sapphire nozzle tip 252 as described above.

In operation, the system for initiating a clean flame, needed in the processing of the wafer 26, includes disposing the heating element 246 within an igniter assembly 78 and energizing the heating element 246 so as to bring the assembly 78 to a predetermined ignition temperature. Gas is then passed through an ignition nozzle assembly 248 at a first gas rate pass the igniter assembly 78 to ignite an initiation flame. The initiation flame is then passed by a plurality of nozzles of a nozzle assembly 84 to ignite a plurality of flames from the nozzles. After the plurality of nozzles of the nozzle assembly 84 have been lit, an air dam is passed in front of the initiation flame by actuating the air knife 250. A non-flammable gas is then passed through the initiator nozzle 248 at a second predetermined rate. In this regard, a second predetermined rate can be greater than the rate of fuel passing through the nozzle. This prevents blow back into the ignition system to the equipment. The use of the air knife 250 allows for the extinguishment of the initiation flame without disruption of the processing flames.

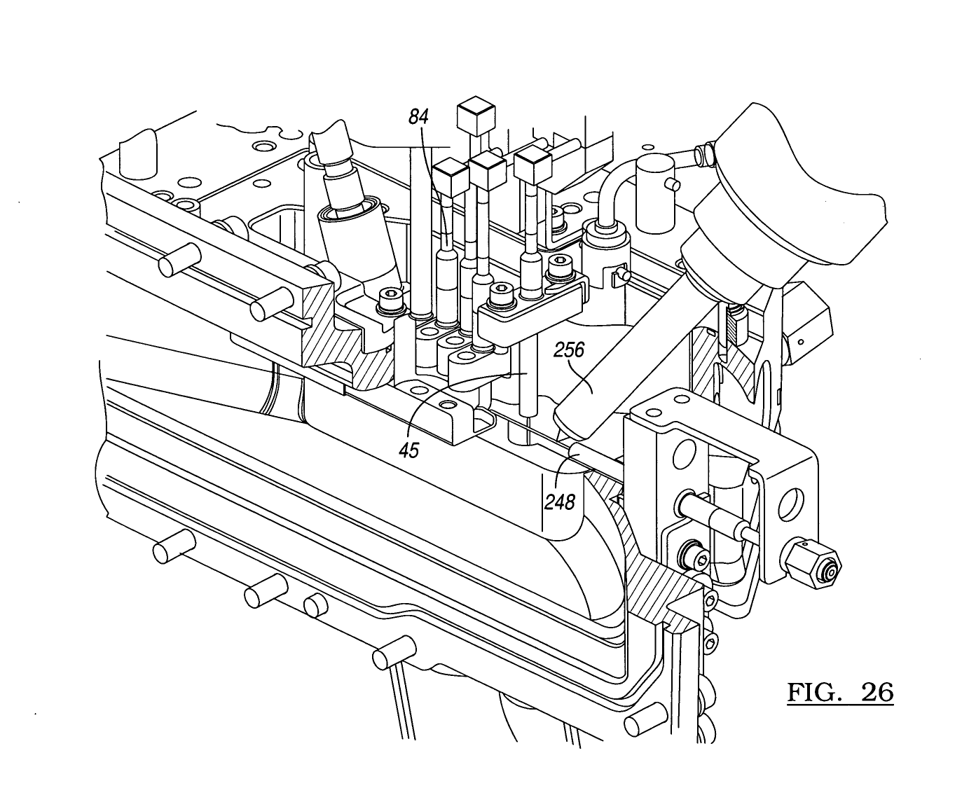

With reference to FIG. 26, shown is an alternate clean ignition system. Similar to the system shown in FIGS. 23A and 23B, the ignition system includes a nozzle 248 for injecting pressurized fuel in proximity to the nozzle assembly 84. This nozzle 248 produces gas jet, which is temporally changed into a plasma and ignited by a very high intensity laser 256. It is envisioned that the ignition system can be disconnected by either shutting off the source of the plasma gas, or disengaging the laser 256.

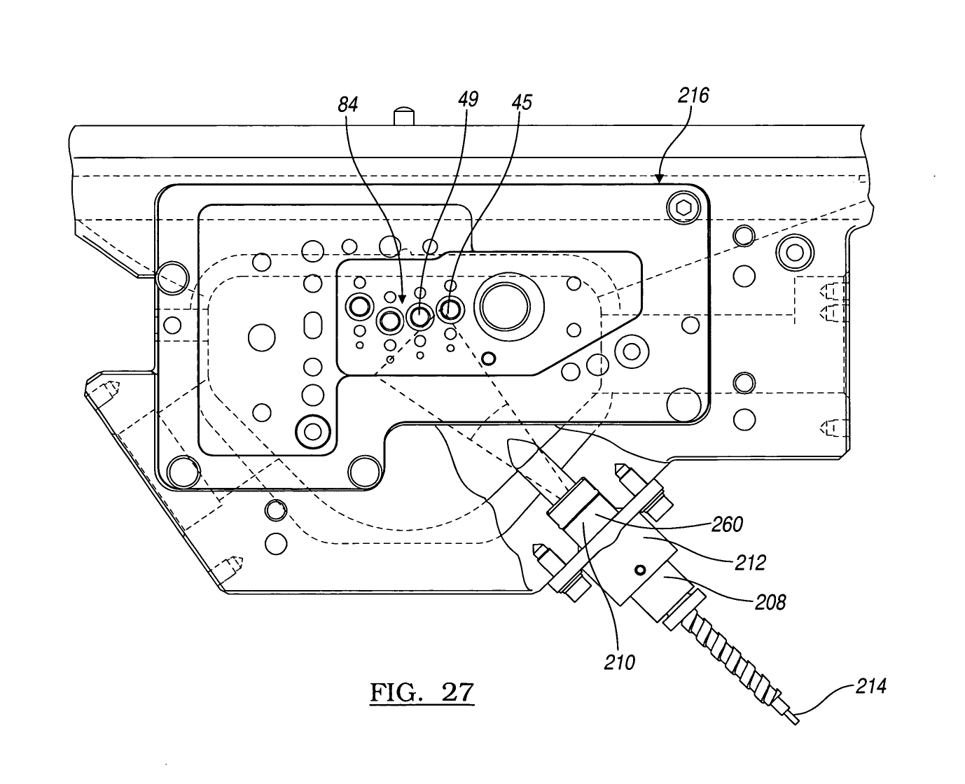

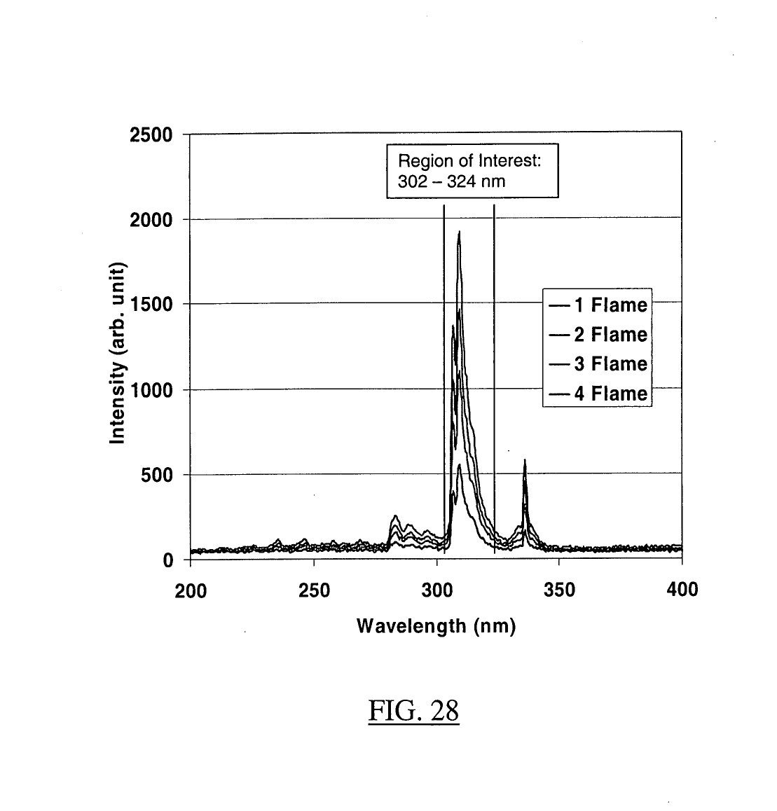

As shown in FIG. 27, optical analysis electronics (not shown) are connected to a fiber optic coupler 210 disposed in the upper section 38 of the isolator 25 in position to receive photon emission from reactive processes. The optical analysis electronics are used to observe and analyze reactive processes to determine presence of reactive species and/or relative concentration of reactive species. In another alternative mode of this feature, optical emission spectroscopy can be used to infer etch end points based on reactive species and/or etched products observed to be present in the region where the chemical reaction in taking place.

FIG. 27 represents a top view of a flame sense system for use in the wafer processing system according to FIG. 1A. Shown is the nozzle plate 216 which supports the nozzle assembly 84 having processing nozzles 45 and 49. Directed to the nozzles 45 and 49 is a CCD spectral analyzer 260. The spectrometer is configured to receive emissions from the flames emitted from the nozzles 45 and 49.

FIG. 28 represents an intensity graph for a spectrum of particular interest. In this regard, the graph depicts wavelength between 200 and 400 nm. As can be seen, under the curve of wavelength between 302 and 324 nm varies depending on the number of flames initiated. It is envisioned that the system can determine the quality and quantity of the number of flames being produced by the system by analyzing the spectral output.

The spectral region of interest used for flame sensing with H₂ and O₂ dominated gas mixtures is between about 300 and 325 nm. Emissions around 309 nm is from an intermediate O—H species generated in the flame.

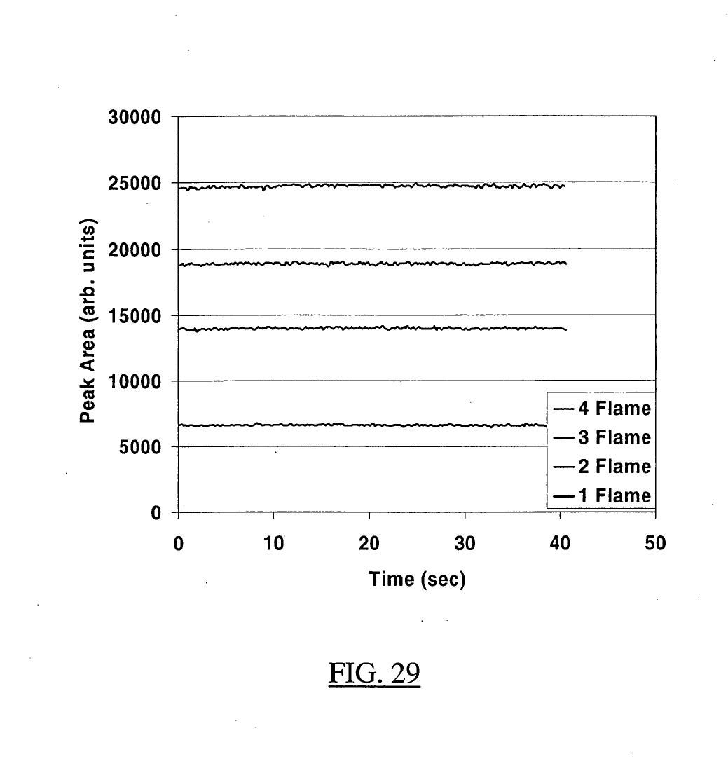

It is envisioned that the mass flow controller 52 of the present system can be coupled to the spectral analyzer 260. In this regard, it is envisioned that should the system determine that one or more nozzles has not be properly emitted, the system will signally fault and can shut the system down. As shown in FIG. 29, varying the number of nozzles, varies the output of the system. This can be detected to determine if the system is functioning properly.

The foregoing discussion discloses and describes exemplary embodiments of the present invention. One skilled in the art will readily recognize from such a discussion, and from the accompanying drawings and claims that various changes, modifications, and variations can be made therein without departing from the spirit and scope of the invention.

1. A method for centering a wafer on a rotatable chuck, said method comprising the steps of:
positioning a wafer adjacent to a micrometer;
rotating the wafer;
recording a plurality of wafer edge locations and rotational increments;
calculating a center offset value for the value of the wafer center with respect to a chuck; and
moving the wafer to a centered position of the chuck.

2. The method according to claim 1 wherein positioning a wafer adjacent the micrometer comprises transporting the wafer on a multi-axis support device.

3. The method according to claim 1 wherein moving the wafer to a central position is positioning the wafer on a fixed support and rotating a portion of the multi-axis support device with respect to the wafer and engaging the wafer.

4. The method according to claim 3 wherein moving the wafer to a centered position is translating the center of a support device chuck to the center of the wafer.

5. The method according to claim 1 further comprising calculating the center of the wafer using a least-squares fitting routine.

6. A method of centering a wafer within a processing machine having a multi-axis support:
rotating the wafer adjacent to an edge location measuring device;
measuring a wafer edge location as a function of rotation angle;
calculating the center of the wafer; and
adjusting the location of the wafer with respect to the multi-axis support.

7. The method according to claim 6 further comprising moving the wafer to a processing location.

8. The method according to claim 6 wherein adjusting the location of the wafer with respect to the multi-axis support is positioning the wafer at affixed location and moving a center of the multi-axis support to a calculated center of the wafer.

9. The method according to claim 6 wherein calculating the center of the wafer is calculating the wafer center using a least-squares fit methodology.

10. The method according to claim 9 further comprising translating the wafer to a measure location a second time after adjusting the location of the wafer with respect to the multi-axis support.

11. The method according to claim 10 further comprising adjusting the location of the wafer with respect to the multi-axis support if the center of the wafer is at a distance greater than a predetermined distance from a chuck center.

12. A method of processing wafer comprising:
positioning a wafer on a chuck of a R,Z-θ movable wafer support structure;
moving the wafer to an edge measurement device;
rotating the wafer with respect to the measurement device;
measuring the location of the wafer's edge as a function of the wafer rotation angle;
calculating the wafer center location; and
moving the wafer center location to a chuck center location.

13. The method according to claim 12 wherein moving the wafer to an edge measuring device is raising the wafer from a loading position.

14. The method according to claim 12 wherein calculating the wafer center location is calculating the wafer center location using a least-squares fit methodology.

15. The method according to claim 12 wherein measuring the location of the wafer's edge as a function of wafer rotation angle is measuring at least forty discrete locations of the wafer's edge.

16. The method of processing a wafer according to claim 12 further comprising translating the wafer from a measurement location to a processing location.

17. The method according to claim 16 further comprising applying a flame to an edge of the wafer at the processing location.

18. The method according to claim 12 wherein moving the wafer to an edge measuring device is moving the wafer to a laser micrometer.

19. The method according to claim 12 wherein rotating the wafer is rotating the wafer using the movable wafer support.

20. The method according to claim 12 wherein moving the wafer center to a chuck location center comprises moving the chuck.
